(19) United States
(12) Patent Application Publication
(10) Pub. No.: US 2026/0040638 A1
(43) Pub. Date: Feb. 5, 2026

(54) SEMICONDUCTOR DEVICE AND METHOD OF MANUFACTURING THE SAME

(71) Applicant: Renesas Electronics Corporation, Tokyo (JP)

(72) Inventor: Yasutaka NAKASHIBA, Tokyo (JP)

(21) Appl. No.: 19/253,420

(22) Filed: Jun. 27, 2025

(30) Foreign Application Priority Data
Jul. 31, 2024 (JP) 2024-124976

(51) Int. Cl. H10D 62/10; H01L 23/528; H10D 30/01; H10D 30/63; H10D 30/65; H10D 62/60; H10D 64/27; H10D 84/80

(52) U.S. Cl. CPC H10D 62/124; H01L 23/5283; H10D 30/025; H10D 30/027; H10D 30/0281; H10D 30/63; H10D 30/655; H10D 62/102; H10D 62/60; H10D 64/518; H10D 84/817

(57) ABSTRACT

A semiconductor device includes a semiconductor substrate into which a first impurity of an n-type is introduced, an epitaxial layer formed on the semiconductor substrate and into which a second impurity of the n-type is introduced, and a semiconductor region of the n-type formed in a portion of the epitaxial layer located under the first portion, into which a third impurity of the n-type is introduced and which has an impurity concentration higher than an impurity concentration of the epitaxial layer.

### CROSS-REFERENCE TO RELATED APPLICATIONS

The disclosure of Japanese Patent Application No. 2024-124976 filed on Jul. 31, 2024 including the specification, drawings and abstract is incorporated herein by reference in its entirety.

### BACKGROUND

The present invention relates to a semiconductor device and a manufacturing technique of the same, and more particularly to a technique that is effective when applied to a semiconductor device including, for example, a power transistor and a Lateral Diffused Metal Oxide Semiconductor Field Effect Transistor (LDMOSFET) on a single semiconductor substrate.

There are disclosed techniques listed below.
Patent Document 1 Japanese Unexamined Patent Application Publication No. 2024-71994
Patent Document 2 Japanese Unexamined Patent Application Publication No. 2024-71995

Patent Document 1 describes a technique related to a semiconductor device including a power transistor and an LDMOSFET on one semiconductor chip.

Patent Document 2 describes a technique related to a semiconductor device including a power transistor and an LDMOSFET on one semiconductor chip.

### SUMMARY

The configuration in which a power transistor, asa component of an output circuit and a MOSFET, as a component of a control circuit that controls the output circuit are mounted on a single semiconductor substrate is advantageous in view of reducing mounting costs and miniaturizing a semiconductor device.

However, in power transistors, reducing the on-resistance is crucial. Meanwhile, when a power transistor and a MOSFET are mounted on a single semiconductor substrate, the MOSFET is required to have a higher breakdown voltage than the avalanche breakdown voltage of the power transistor.

Therefore, it is desirable to reduce the thickness and increase the impurity concentration of the epitaxial layer formed on the semiconductor substrate in order to reduce the on-resistance of the power transistor. On the other hand, in the MOSFET, it is desirable to increase the thickness and reduce the impurity concentration of the epitaxial layer formed on the semiconductor substrate in order to ensure the breakdown voltage higher than the avalanche breakdown voltage of the power transistor.

Specifically, when a power transistor and a MOSFET are mounted on a single semiconductor substrate, in order to achieve both a reduction in the on-resistance of the power transistor and an improvement in the breakdown voltage of the MOSFET, mutually contradictory characteristics are required for the epitaxial layer formed on the semiconductor substrate. Therefore, in a semiconductor device in which a power transistor and a MOSFET are mounted on a single semiconductor substrate, some ingenuity is required to achieve both a reduction in the on-resistance of the power transistor and an improvement in the breakdown voltage of the LDMOSFET.

Other problems and novel characteristics will become clear from the description in the present specification and the attached drawings.

According to one embodiment, a semiconductor device includes a semiconductor substrate into which a first impurity of a first conductivity type is introduced, a semiconductor layer formed on the semiconductor substrate and into which a second impurity of the first conductivity type is introduced, an element formation layer formed on the semiconductor layer and having a first portion and a second portion, and a semiconductor region of the first conductivity type formed in a portion of the semiconductor layer located under the first portion, into which a third impurity of the first conductivity type is introduced and which has an impurity concentration higher than an impurity concentration of the semiconductor layer.

According to one embodiment, a method of manufacturing a semiconductor device includes (a) preparing a semiconductor substrate into which a first impurity of a first conductivity type is introduced, (b) introducing a third impurity of a first conductivity type having a thermal diffusion coefficient greater than that of the first impurity into a first surface portion of the semiconductor substrate, (c) after the above (b), forming an epitaxial layer into which a second impurity of a first conductivity type is introduced is formed by epitaxial growth on the semiconductor substrate.

According to one embodiment, a method of manufacturing a semiconductor device includes (a) preparing a semiconductor substrate into which a first impurity of a first conductivity type is introduced, (b) forming an epitaxial layer having a first impurity concentration into which a second impurity of the first conductivity type is introduced is formed by epitaxial growth on the semiconductor substrate, (c) introducing a third impurity of the first conductivity type into a first portion of the first epitaxial layer, thereby making an impurity concentration in the first portion greater than the first impurity concentration, and (d) after the above (c), forming a second epitaxial layer into which a fourth impurity of the first conductivity type is introduced is formed by epitaxial growth on the first epitaxial layer.

According to one embodiment, in a semiconductor device in which a power transistor and a MOSFET are mounted on a single semiconductor substrate, it is possible to achieve both a reduction in the on-resistance of the power transistor and an improvement in the breakdown voltage of the MOSFET.

### BRIEF DESCRIPTION OF THE DRAWINGS

FIG. 1 is a diagram explaining a basic concept.

FIG. 2 is a diagram illustrating a first modification of the basic concept.

FIG. 3 is a diagram illustrating a second modification of the basic concept.

FIG. 4 is a diagram illustrating a third modification of the basic concept.

FIG. 5 is a diagram illustrating a fourth modification of the basic concept.

FIG. 6 is a plan view of a semiconductor chip which is a semiconductor device.

FIG. 7A is a diagram illustrating a power transistor formed in a first region, and an n-type MOSFET and a p-type MOSFET formed in a second region, and FIG. 7B is a diagram illustrating an n-type LDMOSFET and a p-type LDMOSFET formed in a third region, and a resistive element formed in a fourth region.

FIG. 8 is a diagram illustrating a wiring structure formed above the power transistor provided in the first region and the MOSFET provided in the second region.

FIG. 9 is a diagram illustrating a wiring structure formed above the LDMOSFET provided in the third region and the resistive element provided in the fourth region.

FIG. 10 is a plan view illustrating a plurality of power transistors.

FIG. 11 is a cross-sectional view taken along line A-A and line B-B illustrated in FIG. 10.

FIG. 12A is a diagram illustrating a manufacturing step of a semiconductor device in the first region and the second region in a first embodiment, and FIG. 12B is a diagram illustrating a manufacturing step of the semiconductor device in the third region and the fourth region in the first embodiment.

FIG. 13A is a diagram illustrating a manufacturing step of the semiconductor device following FIG. 12A, and FIG. 13B is a diagram illustrating a manufacturing step of the semiconductor device following FIG. 12B.

FIG. 14A is a diagram illustrating a manufacturing step of the semiconductor device following FIG. 13A, and FIG. 14B is a diagram illustrating a manufacturing step of the semiconductor device following FIG. 13B.

FIG. 15A is a diagram illustrating a manufacturing step of the semiconductor device following FIG. 14A, and FIG. 15B is a diagram illustrating a manufacturing step of the semiconductor device following FIG. 14B.

FIG. 16A is a diagram illustrating a manufacturing step of the semiconductor device following FIG. 15A, and FIG. 16B is a diagram illustrating a manufacturing step of the semiconductor device following FIG. 15B.

FIG. 17A is a diagram illustrating a manufacturing step of the semiconductor device following FIG. 16A, and FIG. 17B is a diagram illustrating a manufacturing step of the semiconductor device following FIG. 16B.

FIG. 18A is a diagram illustrating a manufacturing step of the semiconductor device following FIG. 17A, and FIG. 18B is a diagram illustrating a manufacturing step of the semiconductor device following FIG. 17B.

FIG. 19A is a diagram illustrating a manufacturing step of the semiconductor device following FIG. 18A, and FIG. 19B is a diagram illustrating a manufacturing step of the semiconductor device following FIG. 18B.

FIG. 20A is a diagram illustrating a manufacturing step of the semiconductor device following FIG. 19A, and FIG. 20B is a diagram illustrating a manufacturing step of the semiconductor device following FIG. 19B.

FIG. 21A is a diagram illustrating a manufacturing step of the semiconductor device following FIG. 20A, and FIG. 21B is a diagram illustrating a manufacturing step of the semiconductor device following FIG. 20B.

FIG. 22A is a diagram illustrating a manufacturing step of the semiconductor device following FIG. 21A, and FIG. 22B is a diagram illustrating a manufacturing step of the semiconductor device following FIG. 21B.

FIG. 23A is a diagram illustrating a manufacturing step of the semiconductor device following FIG. 22A, and FIG. 23B is a diagram illustrating a manufacturing step of the semiconductor device following FIG. 22B.

FIG. 24A is a diagram illustrating a manufacturing step of the semiconductor device following FIG. 23A, and FIG. 24B is a diagram illustrating a manufacturing step of the semiconductor device following FIG. 23B.

FIG. 25A is a diagram illustrating a manufacturing step of the semiconductor device following FIG. 24A, and FIG. 25B is a diagram illustrating a manufacturing step of the semiconductor device following FIG. 24B.

FIG. 26A is a diagram illustrating a manufacturing step of the semiconductor device following FIG. 25A, and FIG. 26B is a diagram illustrating a manufacturing step of the semiconductor device following FIG. 25B.

FIG. 27A is a diagram illustrating a manufacturing step of the semiconductor device following FIG. 26A, and FIG. 27B is a diagram illustrating a manufacturing step of the semiconductor device following FIG. 26B.

FIG. 28A is a diagram illustrating a manufacturing step of the semiconductor device following FIG. 27A, and FIG. 28B is a diagram illustrating a manufacturing step of the semiconductor device following FIG. 27B.

FIG. 29A is a diagram illustrating a manufacturing step of the semiconductor device following FIG. 28A, and FIG. 29B is a diagram illustrating a manufacturing step of the semiconductor device following FIG. 28B.

FIG. 30A is a diagram illustrating a manufacturing step of the semiconductor device following FIG. 29A, and FIG. 30B is a diagram illustrating a manufacturing step of the semiconductor device following FIG. 29B.

FIG. 31A is a diagram illustrating a manufacturing step of the semiconductor device following FIG. 30A, and FIG. 31B is a diagram illustrating a manufacturing step of the semiconductor device following FIG. 30B.

FIG. 32A is a diagram illustrating a manufacturing step of the semiconductor device following FIG. 31A, and FIG. 32B is a diagram illustrating a manufacturing step of the semiconductor device following FIG. 31B.

FIG. 33A is a diagram illustrating a manufacturing step of the semiconductor device following FIG. 32A, and FIG. 33B is a diagram illustrating a manufacturing step of the semiconductor device following FIG. 32B.

FIG. 34A is a diagram illustrating a manufacturing step of the semiconductor device following FIG. 33A, and FIG. 34B is a diagram illustrating a manufacturing step of the semiconductor device following FIG. 33B.

FIG. 35A is a diagram illustrating a manufacturing step of the semiconductor device following FIG. 34A, and FIG. 35B is a diagram illustrating a manufacturing step of the semiconductor device following FIG. 34B.

FIG. 36A is a diagram illustrating a manufacturing step of the semiconductor device following FIG. 35A, and FIG. 36B is a diagram illustrating a manufacturing step of the semiconductor device following FIG. 35B.

FIG. 37A is a diagram illustrating a manufacturing step of the semiconductor device following FIG. 36A, and FIG. 37B is a diagram illustrating a manufacturing step of the semiconductor device following FIG. 36B.

FIG. 38A is a diagram illustrating a manufacturing step of a semiconductor device in the first region and the second region in a second embodiment, and FIG. 38B is a diagram illustrating a manufacturing process of the semiconductor device in the third region and the fourth region in the second embodiment.

FIG. 39A is a diagram illustrating a manufacturing step of the semiconductor device following FIG. 38A, and FIG. 39B is a diagram illustrating a manufacturing step of the semiconductor device following FIG. 38B.

FIG. 40A is a diagram illustrating a manufacturing step of the semiconductor device following FIG. 39A, and FIG. 40B is a diagram illustrating a manufacturing step of the semiconductor device following FIG. 39B.

### DETAILED DESCRIPTION

In all the drawings for explaining the embodiments, the same reference numerals are assigned to the same components in principle, and repeated descriptions are omitted. Note that hatching may be applied even in plan views to improve the clarity of the drawings. Furthermore, the size and scale of each element in each drawing have been appropriately changed for reasons such as making the drawing easier to see, and the embodiments are not limited to these size and scale.

An X direction, Y direction, and Z direction described in the embodiments are perpendicular to each other. In the embodiments, the Z direction will be described as the vertical direction, height direction, or thickness direction of a structure. Also, expressions such as a “ground plan” or “plan view” refer to a “plane” composed of the X direction and the Y direction and mean viewing this “plane” from the Z direction.

### Basic Concept

For example, a semiconductor device is being developed that use a power transistor as an output circuit while using a planar-type MOSFET or LDMOSFET in the control circuit that controls the output circuit. This semiconductor device is referred to as an Intelligent Power Device (IPD).

As a form of semiconductor device that makes up the IPD, for example, there is a form in which a power transistor, as a component of the output circuit, and an LDMOSFET, as a component of the control circuit, are formed on a single semiconductor substrate. A semiconductor device of this form is advantageous costs and miniaturizing a in view of reducing mounting semiconductor device, as described in the section “SUMMARY”. However, in the IPD, some ingenuity is required to achieve both a reduction in the on-resistance of the power transistor and an improvement in the breakdown voltage of the LDMOSFET.

Therefore, the following describes the basic concept of achieving both a reduction in the on-resistance of the power transistor and an improvement in the breakdown voltage of the LDMOSFET in the IPD.

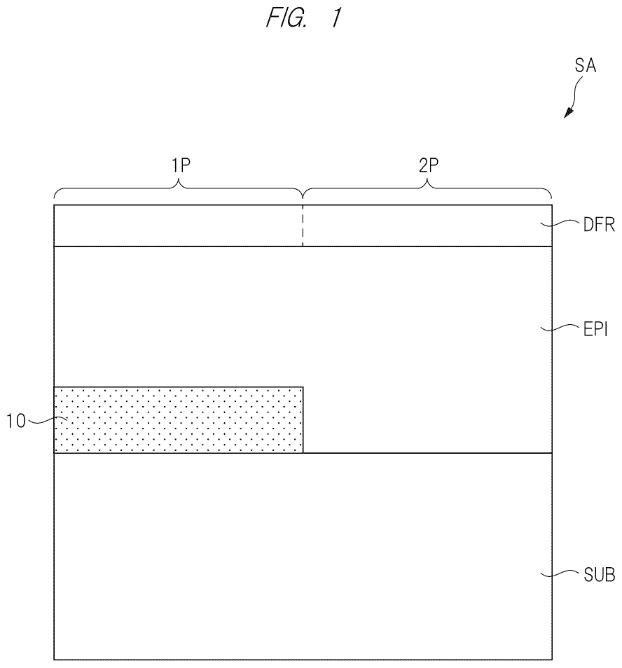

FIG. 1 is a diagram explaining the basic concept.

In FIG. 1, a semiconductor device SA includes a semiconductor substrate SUB, an epitaxial layer EPI, an element formation layer DFR, and a semiconductor region 10.

In the semiconductor substrate SUB, for example, a first impurity of a first conductivity type is introduced. The first impurity of the first conductivity type is an n-type impurity (donor) or a p-type impurity (acceptor).

The epitaxial layer EPI is formed on the semiconductor substrate SUB. In the epitaxial layer EPI, a second impurity of the first conductivity type is introduced. The impurity concentration of the second impurity introduced into the epitaxial layer EPI is lower than the impurity concentration of the first impurity introduced into the semiconductor substrate SUB.

The element formation layer DFR is formed on the epitaxial layer EPI. As illustrated in FIG. 1, the element formation layer DER includes a first portion 1P and a second portion 2P. An output circuit is formed in the first portion 1P, while a control circuit that controls the output circuit is formed in the second portion 2P. The output circuit includes a power transistor. On the other hand, the control circuit includes an LDMOSFET. Therefore, the power transistor is formed in the first portion 1P, while the LDMOSFET is formed in the second portion 2P.

The semiconductor region 10 is formed in a portion of the epitaxial layer EPI located under the first portion 1P. In the semiconductor region 10, a third impurity of the first conductivity type is introduced. The impurity concentration of the third impurity introduced into the semiconductor region 10 is higher than the impurity concentration of the second impurity introduced into the epitaxial layer EPI.

The characteristic of the basic concept is to provide the semiconductor region 10 having the above-mentioned structure. Therefore, according to the basic concept, the semiconductor region 10 is formed under the first portion 1P of the element formation layer DFR in which the power transistor is formed. The on-resistance of the power transistor depends mainly on the characteristics of the epitaxial layer EPI located under the first portion 1P. In this regard, the basic concept is that the semiconductor region 10 having a higher impurity concentration than the epitaxial layer EPI is formed under the first portion 1P in which the power transistor is formed. Considering that regions with a high impurity concentration have a low resistance value, in the basic concept of forming the semiconductor region 10 with an impurity concentration higher than that of the epitaxial layer EPI under the first portion 1P, the presence of the semiconductor region 10 can reduce the on-resistance of the power transistor.

On the other hand, the semiconductor region 10 is not formed in the epitaxial layer EPI under the second portion 2P of the element formation layer DFR in which the LDMOSFET is formed. In this regard, the breakdown voltage of the LDMOSFET depends on the impurity concentration and thickness of the epitaxial layer EPI, but no semiconductor region 10 having an impurity concentration higher than that of the epitaxial layer EPI is formed under the second portion 2P. Considering that the presence of regions with a high impurity concentration reduces the breakdown voltage, in the basic concept, the semiconductor region 10 having an impurity concentration higher than that of the epitaxial layer EPI is not formed under the second portion 2P. For this reason, the impurity concentration and thickness of the epitaxial layer EPI can be designed so that the breakdown voltage of the LDMOSFET can be made higher than the avalanche breakdown voltage of the power transistor.

Therefore, according to the basic concept, in a semiconductor device (IPD) in which a power transistor and a MOSFET are mounted on a single semiconductor substrate, it is possible to achieve both a reduction in the on-resistance of the power transistor and an improvement in the breakdown voltage of the MOSFET.

### First Modification

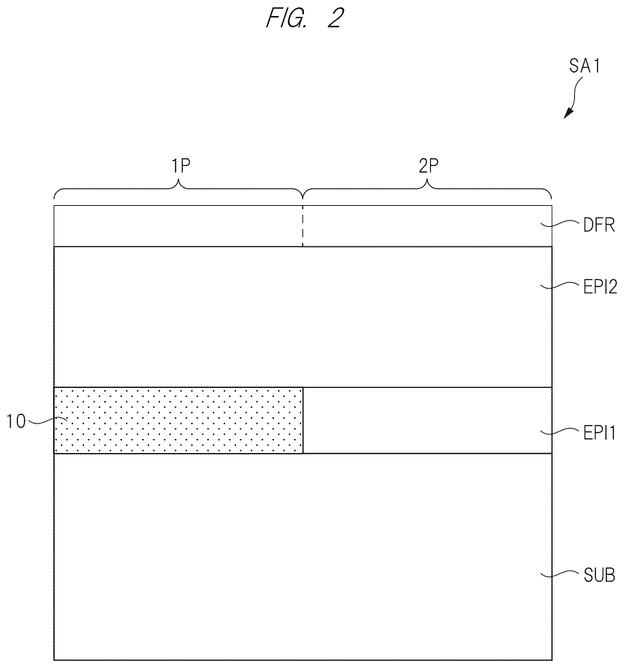

FIG. 2 is a diagram illustrating a first modification of the basic concept.

In FIG. 2, a semiconductor device SA1 includes a semiconductor substrate SUB, an epitaxial layer EPI1, an epitaxial layer EPI2, an element formation layer DFR, and a semiconductor region 10.

In the first modification, the epitaxial layer EPI1 formed on the semiconductor substrate SUB and the epitaxial layer EPI2 formed on the epitaxial layer EPI are provided. For example, the thickness of the epitaxial layer EPI1 is smaller than the thickness of the epitaxial layer EPI2. The semiconductor region 10 is formed in a portion of the epitaxial layer EPI1 located under a first portion 1P. The impurity concentration of the semiconductor region 10 is higher than the respective impurity concentrations of the epitaxial layer EPI1 and the epitaxial layer EPI2.

In the semiconductor device SA1 in the first modification thus configured, the on-resistance of the power transistor can also be reduced by forming the semiconductor region 10 under the first portion 1P, the semiconductor region 10 having an impurity concentration higher than the impurity concentrations of the epitaxial layer EPI1 and the epitaxial layer EPI2. Meanwhile, also in the first modification, the semiconductor region 10 having an impurity concentration higher than that of each of the epitaxial layer EPI1 and the epitaxial layer EPI2 is not formed under the second portion 2P, so that the breakdown voltage of the LDMOSFET can be made higher than the avalanche breakdown voltage of the power transistor.

Therefore, according to the semiconductor device SA1 of the first modification, in a semiconductor device in which a power transistor and a MOSFET are mounted on a single semiconductor substrate, it is possible to achieve both a reduction in the on-resistance of the power transistor and an improvement in the breakdown voltage of the MOSFET.

### Second Modification

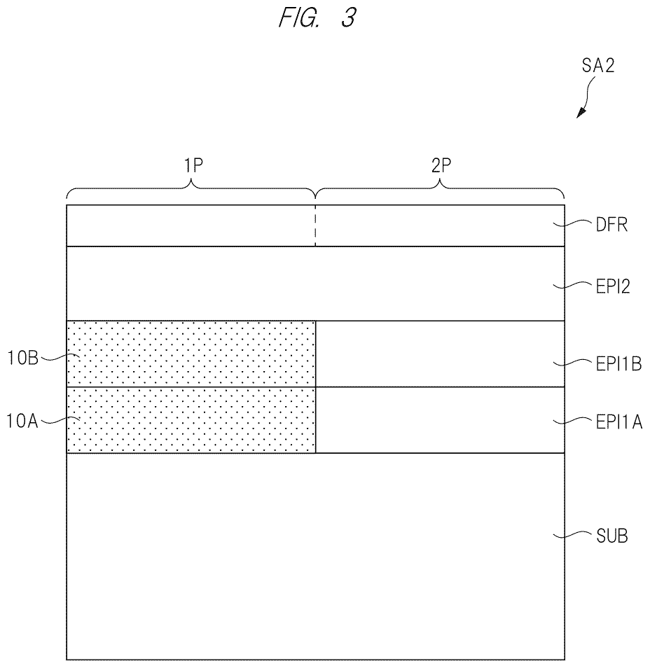

FIG. 3 is a diagram illustrating a second modification of the basic concept.

In FIG. 3, a semiconductor device SA2 includes a semiconductor substrate SUB, an epitaxial layer EPI1A, an epitaxial layer EPI1B, an epitaxial layer EPI2, an element formation layer DER, a semiconductor region 10A, and a semiconductor region 10B.

In the second modification, the epitaxial layer EPI1A formed on the semiconductor substrate SUB, the epitaxial layer EPI1B formed on the epitaxial layer EPI1A, and the epitaxial layer EPI2 formed on the epitaxial layer EPI1B are provided.

The, the semiconductor region 10A is formed in a portion of the epitaxial layer EPI1A located under a first portion 1P. The impurity concentration of the semiconductor region 10A is higher than that of the respective impurity concentrations of the epitaxial layer EPI1A and the epitaxial layer EPI2. Also, the semiconductor region 10B is formed in a portion of the epitaxial layer EPI1B located under the first portion 1P. The impurity concentration of the semiconductor region 10B is higher than that of the respective impurity concentrations of the epitaxial layer EPI1A, the epitaxial layer EPI1B, and the epitaxial layer EPI2. The semiconductor region 10B is formed on the semiconductor region 10A.

For example, the semiconductor region 10A and the semiconductor region 10B are in contact with each other. Similarly, the semiconductor region 10A and the semiconductor region 10B are in contact with each other.

In the semiconductor device SA2 in the second modification thus configured, the on-resistance of the power transistor can also be reduced by forming the semiconductor region 10A and the semiconductor region 10B under the first portion 1P, the semiconductor region 10A and the semiconductor region 10B having an impurity concentration higher than the impurity concentrations of the epitaxial layer EPI1A, the epitaxial layer EPI1B, and the epitaxial layer EPI2. Meanwhile, also in the second modification, the semiconductor region 10A and the semiconductor region 10B having an impurity concentration higher than that of each of the epitaxial layer EPI1A, the epitaxial layer EPI1B, and the epitaxial layer EPI2 are not formed under the second portion 2P, so that the breakdown voltage of the LDMOSFET can be made higher than the avalanche breakdown voltage of the power transistor.

Therefore, according to the semiconductor device SA2 of the second modification, in a semiconductor device in which a power transistor and a MOSFET are mounted on a single semiconductor substrate, it is possible to achieve both a reduction in the on-resistance of the power transistor and an improvement in the breakdown voltage of the MOSFET.

### Third Modification

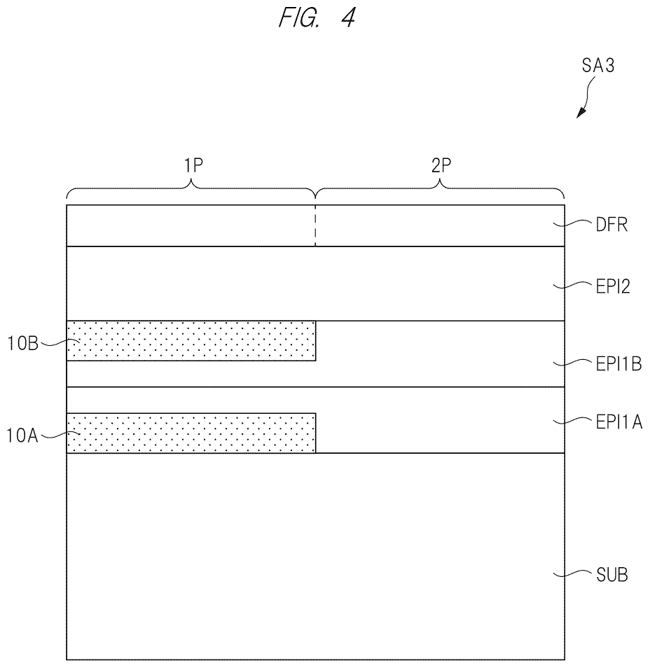

FIG. 4 is a diagram illustrating a third modification of the basic concept.

In FIG. 4, a semiconductor device SA3 includes a semiconductor substrate SUB, an epitaxial layer EPI1A, an epitaxial layer EPI1B, an epitaxial layer EPI2, an element formation layer DFR, a semiconductor region 10A, and a semiconductor region 10B.

In the third modification, the epitaxial layer EPI1A formed on the semiconductor substrate SUB, the epitaxial layer EPI1B formed on the epitaxial layer EPI1A, and the epitaxial layer EPI2 formed on the epitaxial layer EPI1B are provided.

The, the semiconductor region 10A is formed in a portion of the epitaxial layer EPI1A located under a first portion 1P. The impurity concentration of the semiconductor region 10A is higher than that of the respective impurity concentrations of the epitaxial layer EPI1A and the epitaxial layer EPI2. Also, the semiconductor region 10B is formed in a portion of the epitaxial layer EPI1B located under the first portion 1P. The impurity concentration of the semiconductor region 10B is higher than that of the respective impurity concentrations of the epitaxial layer EPI1A, the epitaxial layer EPI1B, and the epitaxial layer EPI2. The semiconductor region 10B is formed over the semiconductor region 10A.

For example, the semiconductor region 10A and the semiconductor region 10B are in contact with each other. Meanwhile, the semiconductor region 10A and the semiconductor region 10B are separated from each other.

In the semiconductor device SA3 in the third modification thus configured, the on-resistance of the power transistor can also be reduced by forming the semiconductor region 10A and the semiconductor region 10B under the first portion 1P, the semiconductor region 10A and the semiconductor region 10B having an impurity concentration higher than the impurity concentrations of the epitaxial layer EPI1A, the epitaxial layer EPI1B, and the epitaxial layer EPI2. Meanwhile, also in the third modification, the semiconductor region 10A and the semiconductor region 10B having an impurity concentration higher than that of each of the epitaxial layer EPI1A, the epitaxial layer EPI1B, and the epitaxial layer EPI2 are not formed under the second portion 2P, so that the breakdown voltage of the LDMOSFET can be made higher than the avalanche breakdown voltage of the power transistor.

Therefore, according to the semiconductor device SA3 of the third modification, in a semiconductor device in which a power transistor and a MOSFET are mounted on a single semiconductor substrate, it is possible to achieve both a reduction in the on-resistance of the power transistor and an improvement in the breakdown voltage of the MOSFET.

### Fourth Modification

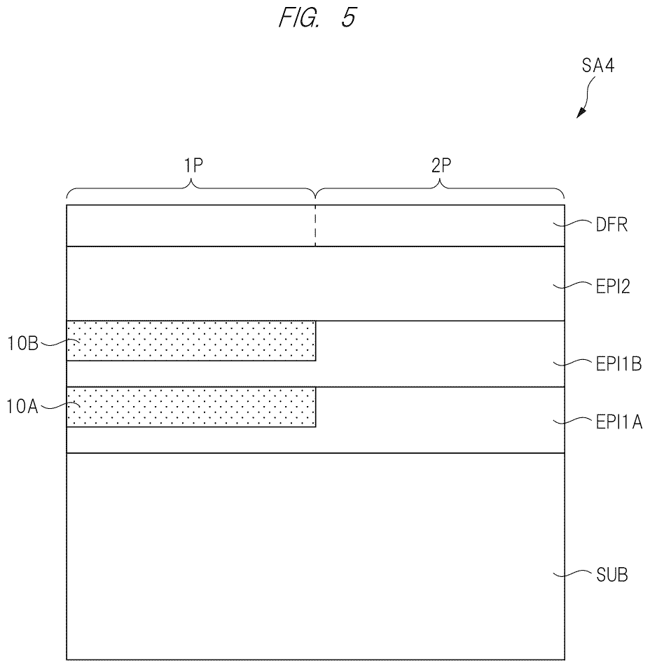

FIG. 5 is a diagram illustrating a fourth modification of the basic concept

In FIG. 5, a semiconductor device SA4 includes a semiconductor substrate SUB, an epitaxial layer EPI1A, an epitaxial layer EPI1B, an epitaxial layer EPI2, an element formation layer DFR, a semiconductor region 10A, and a semiconductor region 10B.

In the fourth modification, the epitaxial layer EPI1A formed on the semiconductor substrate SUB, the epitaxial layer EPI1B formed on the epitaxial layer EPI1A, and the epitaxial layer EPI2 formed on the epitaxial layer EPI1B are provided.

The, the semiconductor region 10A is formed in a portion of the epitaxial layer EPI1A located under a first portion 1P. The impurity concentration of the semiconductor region 10A is higher than that of the respective impurity concentrations of the epitaxial layer EPI1A, the epitaxial layer EPI1B, and the epitaxial layer EPI2. Also, the semiconductor region 10B is formed in a portion of the epitaxial layer EPI1B located under the first portion 1P. The impurity concentration of the semiconductor region 10B is higher than that of the respective impurity concentrations of the epitaxial layer EPI1A, the epitaxial layer EPI1B, and the epitaxial layer EPI2. The semiconductor region 10B is formed over the semiconductor region 10A.

For example, the semiconductor region 10A and the semiconductor substrate SUB are separated from each other. Similarly, the semiconductor region 10A and the semiconductor region 10B are separated from each other.

In the semiconductor device SA4 in the fourth modification thus configured, the on-resistance of the power transistor can also be reduced by forming the semiconductor region 10A and the semiconductor region 10B under the first portion 1P, the semiconductor region 10A and the semiconductor region 10B having an impurity concentration higher than the impurity concentrations of the epitaxial layer EPI1A, the epitaxial layer EPI1B, and the epitaxial layer EP12. Meanwhile, also in the fourth modification, the semiconductor region 10A and the semiconductor region 10B having an impurity concentration higher than that of each of the epitaxial layer EPI1A, the epitaxial layer EPI1B, and the epitaxial layer EPI2 are not formed under the second portion 2P, so that the breakdown voltage of the LDMOSFET can be made higher than the avalanche breakdown voltage of the power transistor.

Therefore, according to the semiconductor device SA4 of the fourth modification, in a semiconductor device in which a power transistor and a MOSFET are mounted on a single semiconductor substrate, it is possible to achieve both a reduction in the on-resistance of the power transistor and an improvement in the breakdown voltage of the MOSFET.

Embodiments that embody the basic concept will be described below.

### First Embodiment

### Configuration of Semiconductor Device

A semiconductor device in a first embodiment includes a semiconductor chip on which an output circuit for driving a load electrically connected to the semiconductor device and a control circuit for controlling the output circuit are formed on a same semiconductor substrate. This is a so-called IPD. For example, the output circuit is an inverter circuit, and the control circuit is a gate driver. The load is, for example, various electronic components such as a motor mounted on a vehicle.

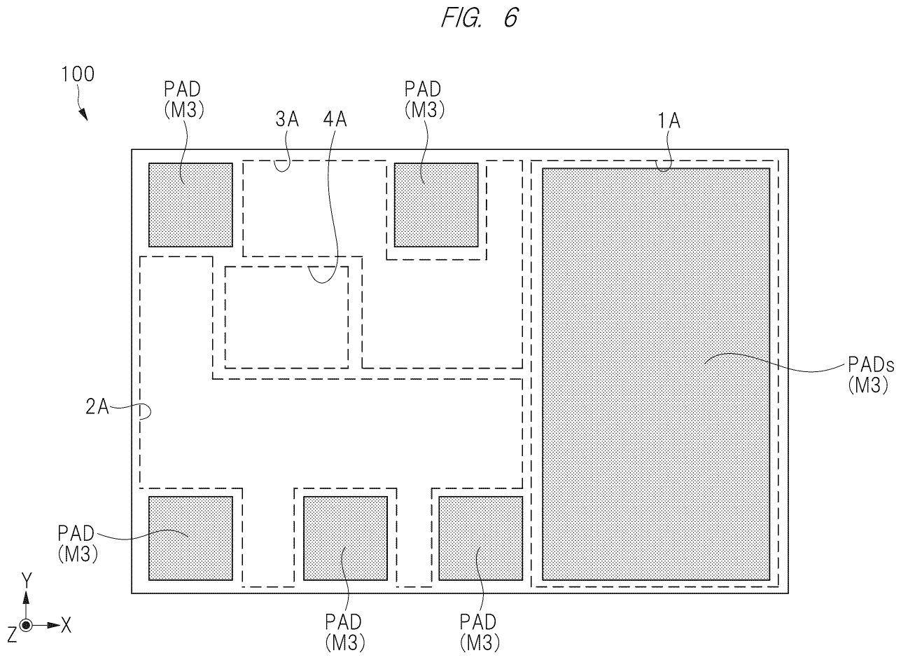

FIG. 6 is a plan view of a semiconductor chip which is a semiconductor device 100.

In FIG. 6, the semiconductor device 100 has a region 1A in which a power transistor for the output circuit is formed, a region 2A in which MOSFETs for the control circuit are formed, a region 3A in which LDMOSFETs for the control circuit are formed, and a region 4A in which a resistive element for the control circuit and the like are formed. The layout of the region 2A, the region 3A, and the region 4A is not limited to the example illustrated in FIG. 6, and can be freely designed as appropriate.

FIG. 6 illustrates a plurality of pads PAD and a source pad PADs which are parts of wirings M3 in the uppermost layer. The source pad PADs is provided over the region 1A and serves as an output terminal of the output circuit. The plurality of pads PAD is provided around the region 2A, the region 3A, and the region 4A. Various signals and a ground potential are supplied from outside the semiconductor device 100 to the control circuit via the plurality of pads PAD.

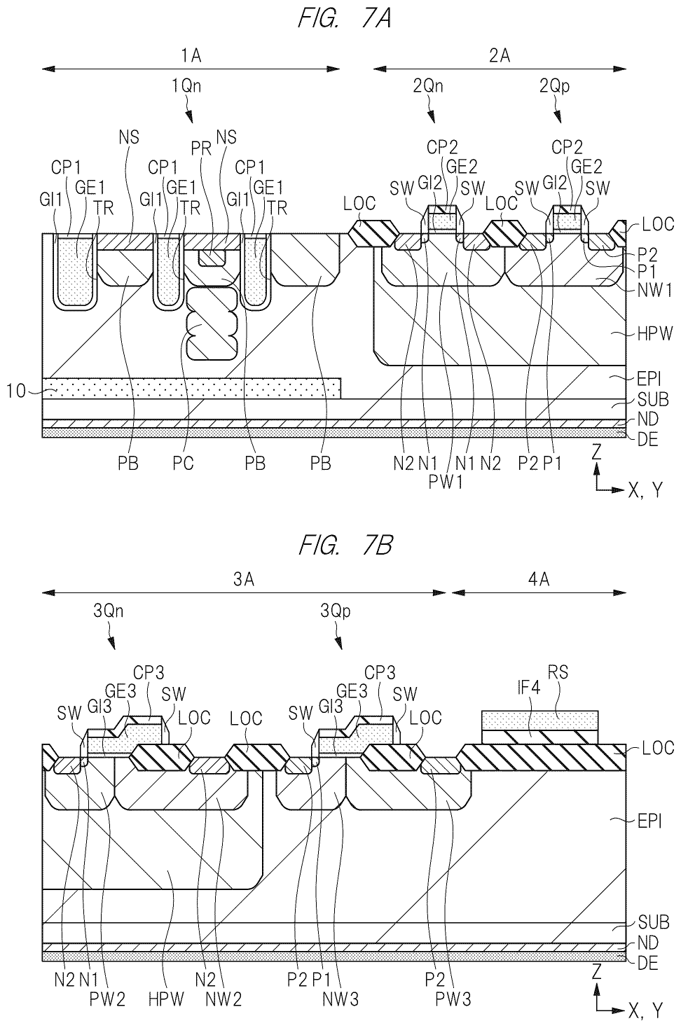

FIG. 7A illustrates a power transistor 1Qn formed in the region 1A, and an n-type MOSFET 2Qn and a p-type MOSFET 2Qp formed in the region 2A. The power transistor 1Qn is a trench-gate type power transistor, and the MOSFET 2Qn and the MOSFET 2Qp are planar type MOSFETs.

FIG. 7B illustrates an n-type LDMOSFET 3Qn and a p-type LDMOSFET 3Qp formed in the region 3A, and a resistive element RS formed in the region 4A. The LDMOSFET 3Qn and the LDMOSFET 3Qp are planar type MOSFETs.

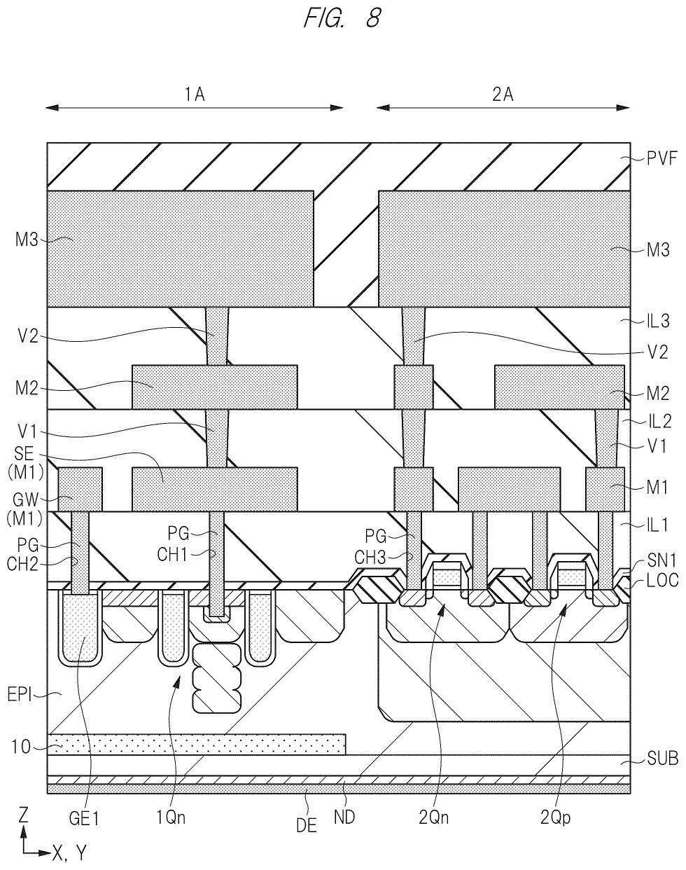

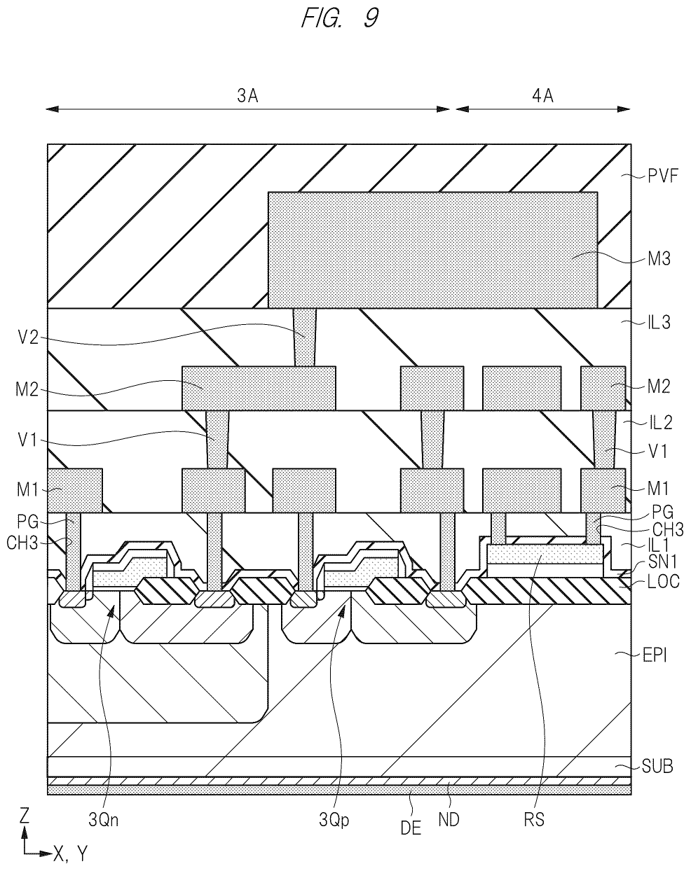

FIG. 8 illustrates a wiring structure formed above the power transistor 1Qn, the MOSFET 2Qn, and the MOSFET 2Qp. FIG. 9 also illustrates a wiring structure formed above the LDMOSFET 3Qn, the LDMOSFET 3Qp, and the resistive element RS.

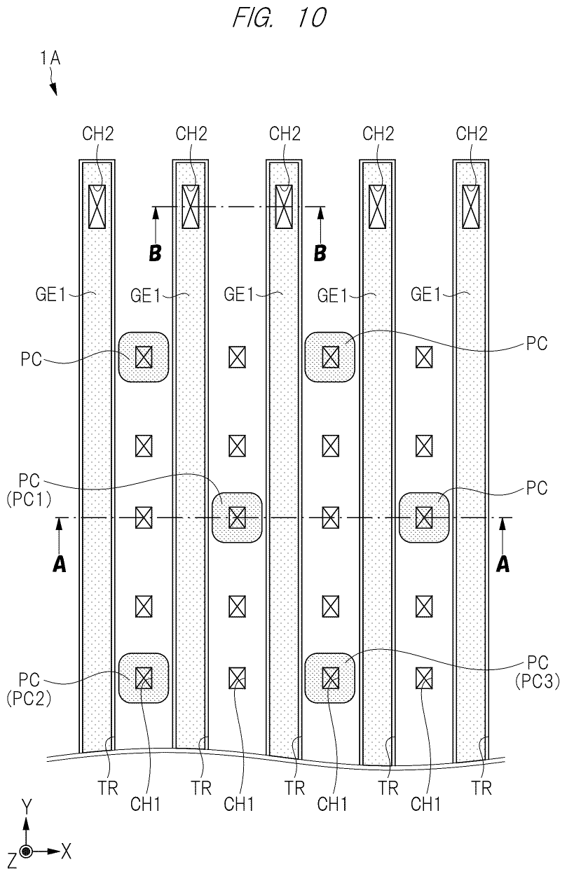

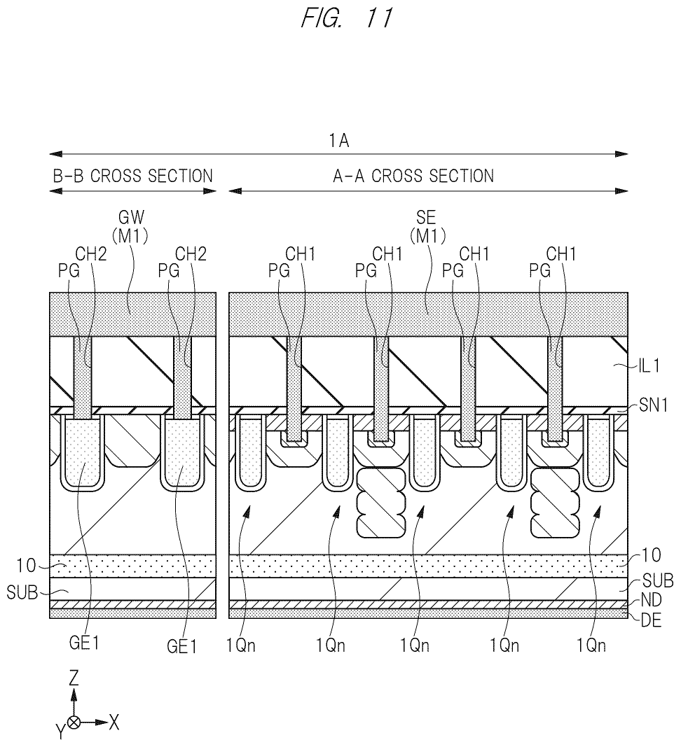

FIG. 7A illustrates a part of a structure of the region 1A. FIGS. 10 and 11 are diagrams illustrating a specific structure of the region 1A. FIG. 10 is a plan view illustrating a plurality of power transistors 1Qn. FIG. 11 is a cross-sectional view taken along line A-A and line B-B illustrated in FIG. 10.

### Configuration of Power Transistor Formed in Region 1A

The structure of the power transistor 1Qn formed in the region 1A will be described with reference to FIGS. 7A, 10 and 11.

The power transistor 1Qn has a gate insulating film GI1, a gate electrode GE1, a body region PB, a source region NS, a high-concentration diffusion region PR, a column region PC, and a cap film CP1. Moreover, the power transistor 1Qn includes, as a drain, a drain region ND, a semiconductor substrate SUB, a semiconductor region 10, and an epitaxial layer EPI.

As illustrated in FIG. 7A, a plurality of trenches TR are formed in the epitaxial layer EPI. A plurality of trenches TR is formed in a stripe pattern, each extending in the Y direction and adjacent to each other in the X direction (see FIG. 10). The gate electrode GE1 is formed inside the trench TR. In FIG. 10, a plurality of holes CH1 are disposed at intervals from each other along the extension direction of the trench TR. A source electrode SE is electrically connected to the source region NS and the body region PB via the hole CH1. A hole CH2 is disposed on the gate electrode GE1 near the end of the trench TR. A gate wiring GW and the gate electrode GE1 are electrically connected via the hole CH2.

As illustrated in FIG. 7A and FIG. 11, the semiconductor device 100 includes an n-type semiconductor substrate SUB. The semiconductor substrate SUB is made of, for example, silicon. A low-concentration n-type epitaxial layer EPI is formed on the semiconductor substrate SUB via the semiconductor region 10.

On the upper surface side of the semiconductor substrate SUB, the trenches TR are formed in the epitaxial layer EPI, the trenches TR reaching a predetermined depth from the upper surface of the epitaxial layer EPI. The depth of the trench TR is, for example, 0.5 μm or more and 2 μm or less. The gate insulating film GI1 is formed inside the trench TR (on the side surfaces and the bottom surface of the trench TR). The gate insulating film GI1 is, for example, a silicon oxide film and has a thickness of 10 nm or more and 20 nm or less.

The gate electrode GE1 is formed inside the trench TR so as to fill the inside of the trench TR via the gate insulating film GI1. The gate electrode GE1 is, for example, a polycrystalline silicon film into which n-type impurities have been introduced. The cap film CP1 is formed on the upper surface of the gate electrode GE so as to cover the upper surface of the gate electrode GE1. The cap film CP1 is an insulating film, and is a silicon oxide film formed by thermally oxidizing the upper surface of the gate electrode GE1 (polycrystalline silicon film). The thickness of the cap film CP1 is thicker than the thickness of the gate insulating film GI1 and the respective thickness of a gate insulating film GI2 and a gate insulating film GI3 described below, and is, for example, 40 nm or more and 60 nm or less.

On the upper surface side of the semiconductor substrate SUB, a p-type body region PB is formed in the epitaxial layer EPI so as to be shallower than the depth of the trench TR. An n-type source region NS is formed in the body region PB. The source region NS has a higher impurity concentration than that of the epitaxial layer EPI.

In the epitaxial layer EPI located under the body region PB, a p-type column region PC is formed. As illustrated in FIG. 10, a plurality of column regions PC are spaced apart at equal intervals in the extension direction (Y direction) of the trenches TR. Also, the plurality of column regions PC are arranged in a staggered pattern. By arranging the p-type column regions PC two-dimensionally in the n-type epitaxial layer EPI, depletion occurs around the column regions PC, thereby improving the breakdown voltage. Moreover, an equilateral triangle is formed by lines connecting the centers of a plurality of column regions PC, such as the column regions PC1, PC2, and PC3. This facilitates the uniform formation of depletion layers extending from each column region (PC). As a result, sufficient depletion is easily achieved between each of the column regions PC.

An n-type drain region ND is formed in the semiconductor substrate SUB on the lower surface side of the semiconductor substrate SUB. The drain region ND has a higher impurity concentration than that of the epitaxial layer EPI. A drain electrode DE is formed on the lower surface of the semiconductor substrate SUB. The drain electrode DE is made from a single layer metal film such as an aluminum film, a titanium film, a nickel film, a gold film, or a silver film, or a laminated film in which these metal films are appropriately laminated. The drain region ND and the drain electrode DE are formed across the region 1A, the region 2A, the region 3A and the region 4A.

The drain region ND, the semiconductor substrate SUB, the semiconductor region 10, and the epitaxial layer EPI form the drain of the power transistor 1Qn. A power supply potential is supplied as a drain potential from outside the semiconductor device 100 to the drain region ND, the semiconductor substrate SUB, the semiconductor region 10, and the epitaxial layer EPI via the drain electrode DE.

As illustrated in FIG. 11, a silicon nitride film SN1 and an interlayer insulating film IL1 are formed on the upper surface of the epitaxial layer EPI so as to cover the gate electrode GE1. The interlayer insulating film IL1 is formed on the silicon nitride film SN1. The thickness of the silicon nitride film SN1 is, for example, 10 nm or more and 20 nm or less. The thickness of the interlayer insulating film IL1 is, for example, 700 nm or more and 900 nm or less. The interlayer insulating film IL1 is made from, for example, a laminated film of a thin silicon oxide film and a thick silicon oxide film containing boron and phosphorus (BPSG: Boro Phospho Silicate Glass film).

Holes CH1 are formed in the interlayer insulating film IL1, the silicon nitride film SN1, the source region NS, and the body region PB. The bottom of the hole CH1 is located inside the body region PB. In the vicinity of the bottom of the hole CH1, a high-concentration diffusion region PR is formed in the body region PB.

The high-concentration diffusion region PR has a higher impurity concentration than that of the body region PB. Also, a hole CH2 is formed in the interlayer insulating film IL1 and the silicon nitride film SN1 so as to penetrate the cap film CP1 and reach the gate electrode GE1.

A plug PG is formed inside each of the holes CH1 and CH2. A plurality of wirings M1 is formed on the interlayer insulating film IL1. In the region 1A, parts of the plurality of wirings M1 function as the source electrode SE and the gate wiring GW. The source electrode SE is electrically connected to the source region NS, the body region PB, and the high-concentration diffusion region PR via the plugs PG inside the holes CH1. The gate wiring GW is electrically connected to and the gate electrode GE1 via the plugs PG inside the holes CH2.

The gate wiring GW is electrically connected to semiconductor elements such as a MOSFET 2Qn, a MOSFET 2Qp, a LDMOSFET 3Qn, a LDMOSFET 3Qp and a resistive element RS via other wirings such as wirings M1 in the region 2A, the region 3A and the region 4A. Therefore, the potential supplied to the gate electrode GE1 is controlled by the control circuits in the region 2A, the region 3A and the region 4A including the above-mentioned semiconductor elements.

The plug PG is formed from a laminated film of a barrier metal film and a conductive film formed on the barrier metal film. The barrier metal film is, for example, a laminated film of a titanium film and a titanium nitride film. The conductive film is, for example, a tungsten film.

Also, the wiring M1 is formed from a laminated film including a first barrier metal film, a conductive film formed on the first barrier metal film, and a second barrier metal film formed on the conductive film. The first barrier metal film is, for example, a laminated film of a titanium film and a titanium nitride film. The conductive film is, for example, an aluminum alloy film with added copper or silicon, or an aluminum film. The second barrier metal film is, for example, a laminated film of a titanium film and a titanium nitride film.

### Configurations of MOSFETs 2Qn and 2Qp Formed in Region 2A

The structures of the MOSFET 2Qn and the MOSFET 2Qp formed in the region 2A will be described with reference to FIG. 7A.

The MOSFET 2Qn includes a gate insulating film GI2, a gate electrode GE2, a cap film CP2, sidewall spacers SW, a well region PW1, impurity regions N1 and impurity regions N2. The source region and the drain region of the MOSFET 2Qn are formed from the impurity regions N1 and the impurity regions N2.

The MOSFET 2Qp includes a gate insulating film GI2, a gate electrode GE2, a cap film CP2, sidewall spacers SW, a well region NW1, impurity regions P1 and impurity regions P2. The source region and the drain region of the MOSFET 2Qp are formed from the impurity regions P1 and the impurity regions P2.

In the epitaxial layer EPI in the region 2A and the region 3A, a p-type well region HPW is formed. The well region HPW is provided mainly to separate the well region NW1 formed in the region 2A and a well region NW2 formed in the region 3A from the n-type epitaxial layer EPI.

In the well region HPW in the region 2A, the p-type well region PW1 and the n-type well region NW1 are formed. The gate insulating film GI2 is formed on each of the well region PW1 and the well region NW1. The gate insulating film GI2 is, for example, a silicon oxide film and has a thickness of 10 nm or more and 20 nm or less. The gate electrode GE2 is formed on the gate insulating film GI2.

The MOSFET 2Qn and MOSFET 2Qp formed in the region 2A are provided for high-speed operation. Accordingly, the MOSFET 2Qn and the MOSFET 2Qp are driven at an operating voltage lower than that of the power transistor 1Qn formed in the region 1A. Therefore, the material contained in the gate electrode GE2 is different from the material contained in the gate electrode GE1, and the gate electrode GE2 has a sheet resistance lower than the sheet resistance of the material contained in the gate electrode GE1. Moreover, the gate electrode GE2 is formed manufacturing step different from that of the gate electrode GE1. The gate electrode GE2 is made from, for example, a laminated film of a polycrystalline silicon film into which n-type impurities have been introduced and a tungsten silicide film formed on the polycrystalline silicon film.

The thickness of the polycrystalline silicon film is, for example, 60 nm or more and 100 nm or less. The thickness of the tungsten silicide film is, for example, 80 nm or more and 120 nm or less. Further, the impurity concentration of the polycrystalline silicon film included in the gate electrode GE2 is equal to or higher than the impurity concentration of the polycrystalline silicon film included in the gate electrode GE1.

The cap film CP2 is formed on the upper surface of the gate electrode GE2. The cap film CP2 is an insulating film, for example, a silicon oxide film. The thickness of the cap film CP2 is, for example, 100 nm or more and 150 nm or less. The sidewall spacers SW are formed on the side surfaces of the gate electrode GE2. The sidewall spacer SW is made from, for example, a silicon oxide film.

In the well region PW1, n-type impurity regions N1 and n-type impurity regions N2 are formed. The well region PW1 interposed between the pair of impurity regions N1 and located under the gate electrode GE2 becomes a channel region of the MOSFET 2Qn. The impurity regions N2 are formed to deeper positions than the impurity regions N1 and have a higher impurity concentration than that of the impurity regions N1.

In the well region NW1, p-type impurity regions P1 and p-type impurity regions P2 are formed. The well region NW1 interposed between the pair of impurity regions P1 and located under the gate electrode GE2 becomes a channel region of the MOSFET 2Qp. The impurity regions P2 are formed to deeper positions than the impurity regions P1 and have a higher impurity concentration than that of the impurity regions P1.

The region 1A, the region 2A, the region 3A, and the region 4A are each partitioned by element isolation portions LOC formed in the epitaxial layer EPI. The element isolation portion LOC is, for example, a silicon oxide film and has a thickness of 300 nm or more and 600 nm or less. The element isolation portions LOC are also formed at the boundary between the MOSFET 2Qn and the MOSFET 2Qp in the region 2A and at the boundary between the LDMOSFET 3Qn and the LDMOSFET 3Qp in the region 3A.

### Configuration of LDMOSFETs 3Qn and 3Qp Formed in Region 3A

The structures of the LDMOSFET 3Qn and the LDMOSFET 3Qp formed in the region 3A will be described with reference to FIG. 7B.

The LDMOSFET 3Qn includes a gate insulating film GI3, a gate electrode GE3, a cap film CP3, sidewall spacers SW, a well region PW2, element isolation portions LOC, an impurity region N1 and impurity regions N2. The source region the LDMOSFET 3Qn is formed from the impurity region N1 and the impurity regions N2. The drain region of the LDMOSFET 3Qn is formed from a well region NW2 and the impurity regions N2.

The LDMOSFET 3Qp includes a gate insulating film GI3, a gate electrode GE3, a cap film CP3, sidewall spacers SW, a well region NW3, element isolation portions LOC, an impurity region P1 and impurity regions P2. The source region the LDMOSFET 3Qp is formed from the impurity region P1 and the impurity regions P2. The drain region of the LDMOSFET 3Qn is formed from a well region PW3 and the impurity regions N2.

In the well region HPW formed in the region 3A, the p-type well region PW2 and the n-type well region NW2 are formed. The gate insulating film GI3 is formed on each of the well region PW2 and the well region NW2. The gate electrode GE3 is formed on the gate insulating film GI3. The cap film CP3 is formed on the upper surface of the gate electrode GE3. The sidewall spacers SW are formed on the side surfaces of the gate electrode GE3.

Further, an element isolation portion LOC is formed in a part of the well region NW2. A part of the gate electrode GE3 is formed on the element isolation portion LOC, and an end of the gate electrode GE3 on the drain region side is located on the element isolation portion LOC.

The LDMOSFETs 3Qn and 3Qp are driven at an operating voltage higher than that of the MOSFETs 2Qn and 2Qp formed in the region 2A. For example, a potential of about 5 V is applied to the drain region of the MOSFET 2Qn in the region 2A. Whereas, a potential of about 10 V or higher is applied to the drain region of the LDMOSFET 3Qn in the region 3A. Accordingly, to alleviate the electric field concentration in the drain region, in the LDMOSFET3Qn, the element isolation portion LOC is provided under the gate electrode GE3 on the drain region side.

In the well region PW2, the n-type impurity region N1 and the n-type impurity region N2 are formed. In the well region NW2, the n-type impurity region N2 is formed. The well region PW2, which is interposed between the impurity region N1 and the well region NW2 in the well region PW2 and is located under the gate electrode GE3, becomes a channel region of the LDMOSFET 3Qn.

In the epitaxial layer EPI in the region 3A, the n-type well region NW3 and the p-type well region PW3 are formed. The gate insulating film GI3 is formed on each of the well region NW3 and the well region PW3. The gate electrode GE3 is formed on the gate insulating film GI3. The cap film CP3 is formed on the upper surface of the gate electrode GE3. The sidewall spacers SW are formed on the side surfaces of the gate electrode GE3.

Also, in the LDMOSFET 3Qp, the element isolation portion LOC is formed in a part of the well region NW3 to reduce the electric field concentration in the drain region. A part of the gate electrode GE3 is formed on the element isolation portion LOC, and an end of the gate electrode GE3 on the drain region side is located on the element isolation portion LOC.

In the well region NW3, the p-type impurity region P1 and the p-type impurity region P2 are formed. In the well region PW3, the p-type impurity region P2 is formed. The well region NW3, which is interposed between the impurity region P1 and the well region PW3 in the well region NW3 and is located under the gate electrode GE3, becomes a channel region of the LDMOSFET 3Qp.

The gate insulating film GI3, the gate electrode GE3, the cap film CP3 and the sidewall spacers SW in the region 3A are formed in the same manufacturing step as the gate insulating film GI2, the gate electrode GE2, the cap film CP2 and the sidewall spacers SW in the region 2A, respectively. Therefore, these materials and thicknesses are similar to those described for the MOSFETs 2Qn, and 2Qp in the region 2A.

### Configuration of Resistive Element Formed in Region 4A

The structure of the resistive element RS formed in the region 4A will be described with reference to FIG. 7B

In the epitaxial layer EPI in the region 4A, an element isolation portion LOC is formed.

An insulating film IF4 is formed on the element isolation portion LOC. The insulating film IF4 is, for example, a silicon oxide film and has a thickness of 50 nm or more and 70 nm or less.

The resistive element RS is formed on the insulating film IF4. The resistance element RS needs to be designed such that a high resistance value is achieved. Therefore, the material contained in the resistive element RS has a sheet resistance higher than the sheet resistance of the material contained in the gate electrodes GE1, GE2 and GE3. Moreover, the resistive element RS is formed in a manufacturing step different from that of the electrodes GE1, GE2 and GE3. The resistive element RS is, for example, a polycrystalline silicon film into which p-type impurities have been introduced and has a thickness of 120 nm or more and 180 nm or less.

### Wiring Structure

The wiring structure formed above the power transistor 1Qn, the MOSFET 2Qn, the MOSFET 2Qp, the LDMOSFET 3Qn, the LDMOSFET 3Qp, and the resistive element RS will be described with reference to FIGS. 8 and 9.

Across the region 2A, the region 3A, and the region 4A, a silicon nitride film SN1 and an interlayer insulating film IL1 are formed on the upper surface of the epitaxial layer EPI so as to cover the gate electrodes GE2 and GE3. The material contained in the interlayer insulating film IL1 is the same as the material described in the region 1A.

Here, in the MOSFET 2Qp and the LDMOSFET 3Qp, positive charges may be trapped in the gate insulating films GI2 and GI3, which may lead to “NBTI” degradation. In this regard, since the MOSFET 2Qp and the LDMOSFET 3Qp are covered with the silicon nitride film SN1, injection of positive charges into the gate insulating films GI2 and GI3 can be suppressed, and as a result, the reliability of the semiconductor device 100 can be improved.

In the region 2A, the region 3A, and the region 4A, a plurality of holes CH3 is formed in the interlayer insulating film IL1 and the silicon nitride film SN1. A plug PG is formed inside each of the plurality of holes CH3. A plurality of wirings M1 is formed on the interlayer insulating film IL1. The material contained in the plug PG and the insulating film IL1 is the same as the material described in the configuration of region 1A.

The impurity regions N2, the impurity regions P2 and the resistive element RS are electrically connected to the plurality of wirings M1 via plugs PG inside holes CH3. Although not illustrated, the gate electrode GE2 and the gate electrode GE3 are also electrically connected to the wirings M1 via the plugs PG inside the holes CH3.

Across the region 1A, the region 2A, the region 3A, and the region 4A, an interlayer insulating film IL2 is formed on the interlayer insulating film IL1 so as to cover the plurality of wirings M1.

The interlayer insulating film IL2 is, for example, a silicon oxide film.

The thickness of the interlayer insulating film IL2 is 650 nm or more and 850 nm or less.

A plurality of vias V1 connected to the plurality of wirings M1 is formed in the interlayer insulating film IL2. A via V1 is formed by burying a laminated film of a barrier metal film and a conductive film in a contact hole formed in the interlayer insulating film IL2. The barrier metal film is, for example, a titanium nitride film. The conductive film is, for example, a tungsten film.

A plurality of wirings M2 connected to the plurality of vias V1 is formed on the interlayer insulating film IL2. The material contained in the wiring M2 is the same as the material of the wiring M1. An interlayer insulating film IL3 is formed on the interlayer insulating film IL2 so as to cover the plurality of wirings M2.

The material contained in the interlayer insulating film IL3 is the same as the material of the interlayer insulating film IL2. The thickness of the interlayer insulating film IL3 is, for example, 650 nm or more and 850 nm or less. A plurality of vias V2 connected to the plurality of wirings M2 is formed in the interlayer insulating film IL3. The configuration of via V2 is the same as the configuration of via V1.

A plurality of wirings M3 connected to the plurality of vias V2 is formed on the interlayer insulating film IL3. The wiring M3 is formed from a laminated film of a barrier metal film and a conductive film formed on the barrier metal film. The barrier metal film is, for example, a titanium tungsten film. The conductive film is, for example, an aluminum alloy film with added copper or silicon, or an aluminum film. The thickness of each of the wiring M1 and the wiring M2 is, for example, 300 nm or more and 600 nm or less. Meanwhile, the thickness of the wiring M3 is sufficiently thicker than the thicknesses the wiring M1 and the wiring M2, and is, for example, 3 μm or more and 5 μm or less.

A protective film PVF is formed on the interlayer insulating film IL3 so as to cover the plurality of wirings M3. The protective film PVF is, for example, a polyimide film. The thickness of the protective film PVF is, for example, 4 μm or more and 7 μm or less.

In the protective film PVF on the wirings M3, a first opening (not illustrated) and a plurality of second openings (not illustrated) are formed so that parts of the wirings M3 are exposed. A part of the wiring M3 exposed in the first opening forms a source pad PADs (see FIG. 6) for connection to an external connection member. The parts of the wirings M3 exposed in the second openings form a plurality of pads PAD (see FIG. 6) for connection to external connection members.

The external connection members are, for example, bonding wires made of gold or copper, or clips made of copper plates. By connecting the external connection members onto the source pads PADs and the plurality of pads PAD, the semiconductor device 100 is electrically connected to another semiconductor chip or a wiring board.

### Configuration of Semiconductor Region 10

The semiconductor region 10 will be described with reference to FIGS. 7A and 7B.

As illustrated in FIG. 7A, the semiconductor region 10 is provided in the region 1A in which the power transistor 1Qn is formed, but is not provided in the region 2A in which the MOSFET 2Qn and the MOSFET 2Qp are formed.

Further, as illustrated in FIG. 7B, the semiconductor region 10 is not provided in the region 3A in which the LDMOSFET 3Qn and the LDMOSFET 3Qp are formed, and is also not provided in the region 4A in which the resistive element RS is formed.

The semiconductor region 10 is an n-type semiconductor region. That is, in the semiconductor region 10, an n-type impurity (donor) is introduced, in the same manner as the semiconductor substrate SUB and the epitaxial layer EPI. The impurity concentration of the semiconductor region 10 is higher than the impurity concentration of the epitaxial layer EPI.

Here, the n-type impurity introduced into the semiconductor region 10 is an element different from that of the n-type impurity introduced into the semiconductor substrate SUB. For example, the thermal diffusion coefficient of the n-type impurity introduced into the semiconductor region 10 is greater than the thermal diffusion coefficient of the n-type impurity introduced into the semiconductor substrate SUB. Specifically, the n-type impurity introduced into the semiconductor substrate SUB is arsenic. Whereas, the n-type impurity introduced into the semiconductor region 10 is phosphorus.

### Method of Manufacturing Semiconductor Device

Next, a method of manufacturing the semiconductor device will be described with reference to the drawings.

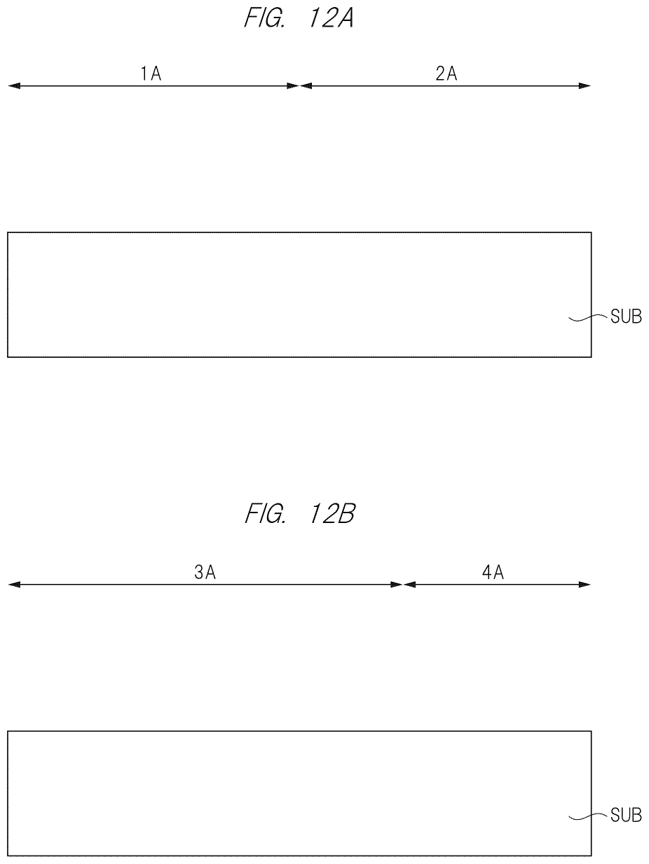

First, as illustrated in FIG. 12A and FIG. 12B, semiconductor substrate SUB is prepared. Arsenic (As), which is an n-type impurity, is introduced into the semiconductor substrate SUB.

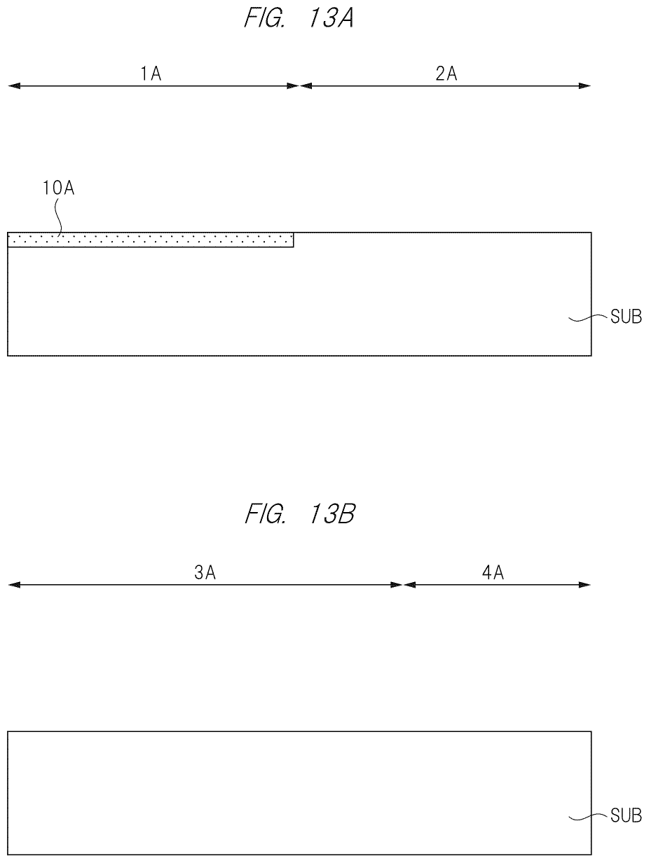

Next, as illustrated in FIGS. 13A and 13B, in the region 1A, an n-type impurity having a greater thermal diffusion coefficient than the n-type impurity introduced into the semiconductor substrate SUB is introduced into near the upper surface of the semiconductor substrate SUB. Specifically, in the region 1A, phosphorus (P), which has a thermal diffusion coefficient greater than that of arsenic, is introduced near the upper surface of the semiconductor substrate SUB to form a semiconductor region 10A. The semiconductor region 10A can be formed, for example, by introducing phosphorus into near the upper surface of the semiconductor substrate SUB in the region 1A by selective ion implantation using a mask.

The impurity concentration of the semiconductor region 10A is, for example, 1×10¹⁵/cm³. It should be noted that phosphorus is not introduced into the regions other than the region 1A, that is, the region 2A, the region 3A, and the region 4A. As a result, the semiconductor region 10A is not formed in the region 2A, the region 3A, and the region 4A.

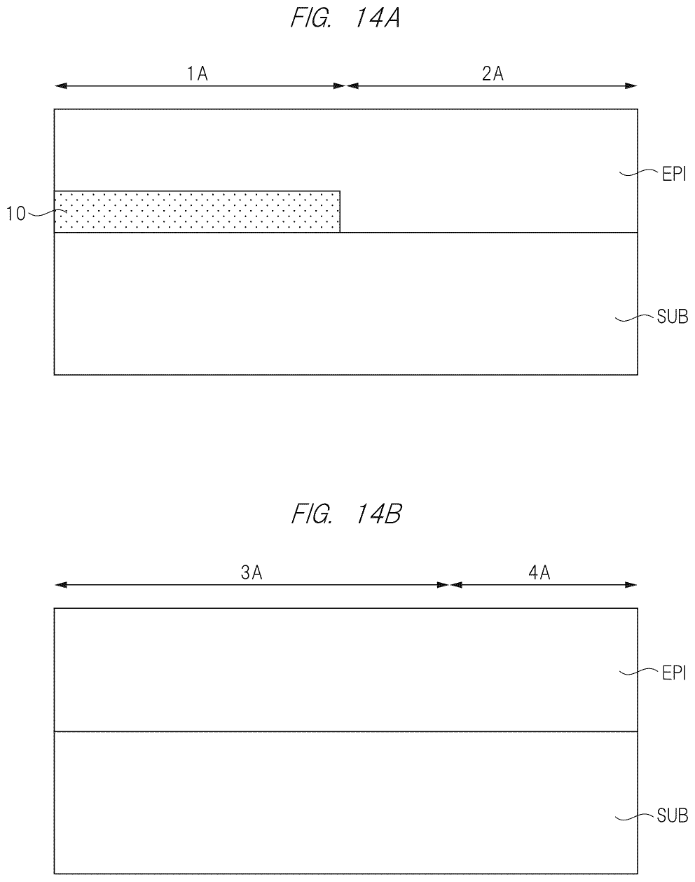

Thereafter, as illustrated in FIGS. 14A and 14B, an epitaxial layer EPI is formed on the semiconductor substrate SUB on which the semiconductor region 10A is formed. Specifically, an epitaxial layer EPI into which phosphorus is introduced is formed on a semiconductor substrate SUB by using an epitaxial growth method. In this step, arsenic introduced into the semiconductor substrate SUB is thermally diffused into the epitaxial layer EPI. Furthermore, the phosphorus introduced into the semiconductor region 10A also thermally diffuses into the epitaxial layer EPI. At this time, the thermal diffusion coefficient of phosphorus is greater than the thermal diffusion coefficient of arsenic. Therefore, as illustrated in FIG. 14A, phosphorus diffuses more upwardly in the epitaxial layer EPI than arsenic does, resulting in the formation of the semiconductor region 10 in the region 1A.

Since the semiconductor region 10 receives phosphorus thermally diffused from the semiconductor region 10A, the impurity concentration of the semiconductor region 10 becomes higher than the impurity concentration of the epitaxial layer EPI.

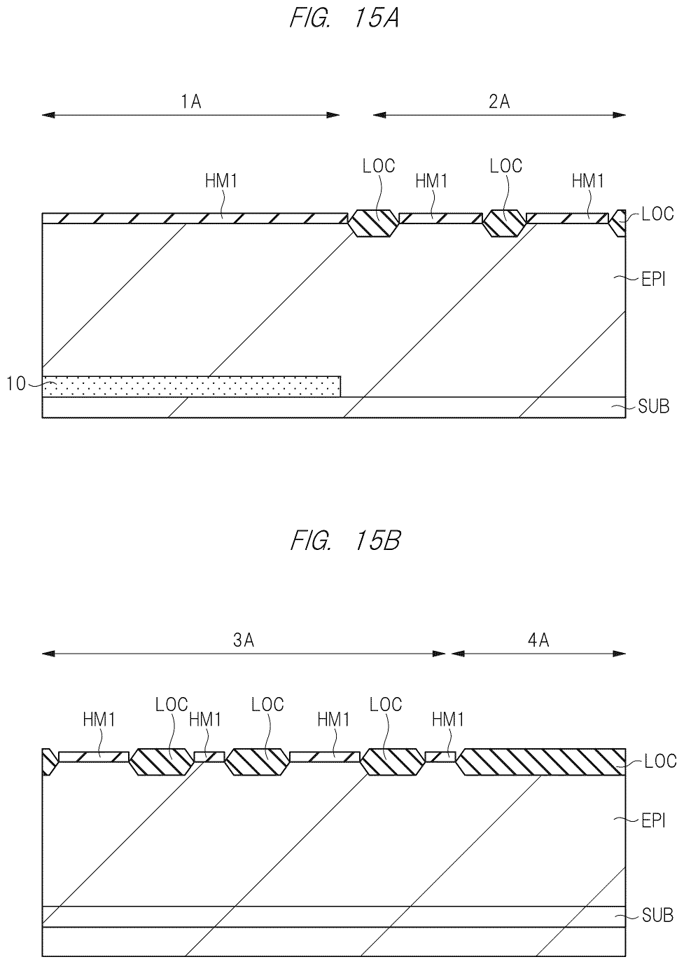

Subsequently, as illustrated in FIGS. 15A and 15B, a silicon oxide film is formed on the upper surface of the epitaxial layer EPI by, for example, thermal oxidation treatment. Next, a silicon nitride film is formed on the silicon oxide film by, for example, a Chemical Vapor Deposition (CVD) method. Then, the silicon oxide film and the silicon nitride film are patterned to form a hard mask HM1 that selectively covers the upper surface of the epitaxial layer EPI. Next, the thermal oxidation treatment is performed on the epitaxial layer EPI to form an element isolation portion LOC made of a silicon oxide film in the epitaxial layer EPI exposed from the hard mask HM1. Then, the hard mask HM1 is removed by an isotropic etching process.

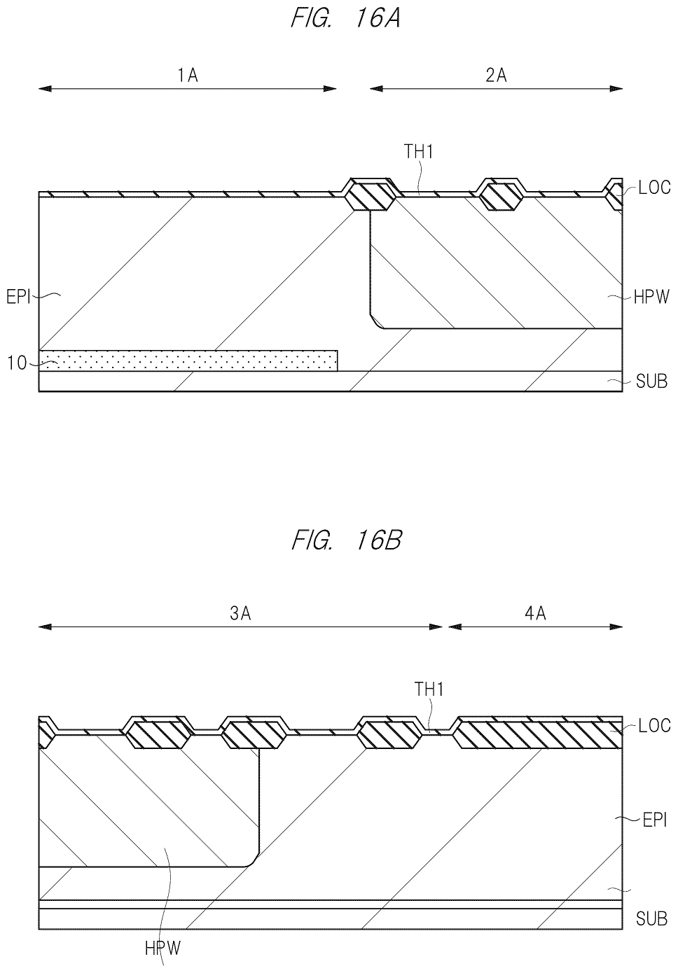

As illustrated in FIGS. 16A and 16B, a through film TH1 made from a silicon oxide film is formed on the upper surface of the epitaxial layer EPI by the thermal oxidation treatment.

Next, ions are selectively implanted from the upper surface side of the epitaxial layer EPI so as to pass through the through film TH1, thereby forming a p-type well region HPW in the epitaxial layer EPI in the region 2A and the region 3A. In the ion implantation, for example, boron (B) is used as the impurity.

Thereafter, heat treatment is performed on the well region HPW. The heat treatment is performed in a nitrogen atmosphere under a condition of, for example, 1150° C. and 90 minutes. This heat treatment causes the impurity contained in the well region HPW to diffuse into the epitaxial layer EPI and become activated.

Since the above-mentioned heat treatment is performed for a relatively long period of time, if the heat treatment is performed after the formation of the gate insulating film GI1, stress is generated from the gate insulating film GI1 into the epitaxial layer EPI, and this stress may cause crystal defects in the epitaxial layer EPI. In addition, the hard mask HM1 and a hard mask HM2 described later contain a silicon nitride film. Even if the heat treatment is performed with the silicon nitride film formed on the upper surface of the epitaxial layer EPI, crystal defects may occur in the epitaxial layer EPI due to the stress of the silicon nitride film. That is, the above-mentioned heat treatment is desirably performed before the formation of the trenches TR and before the formation of the gate insulating film GI1, and is desirably performed in a state in which a silicon nitride film is not formed on the upper surface of the epitaxial layer EPI.

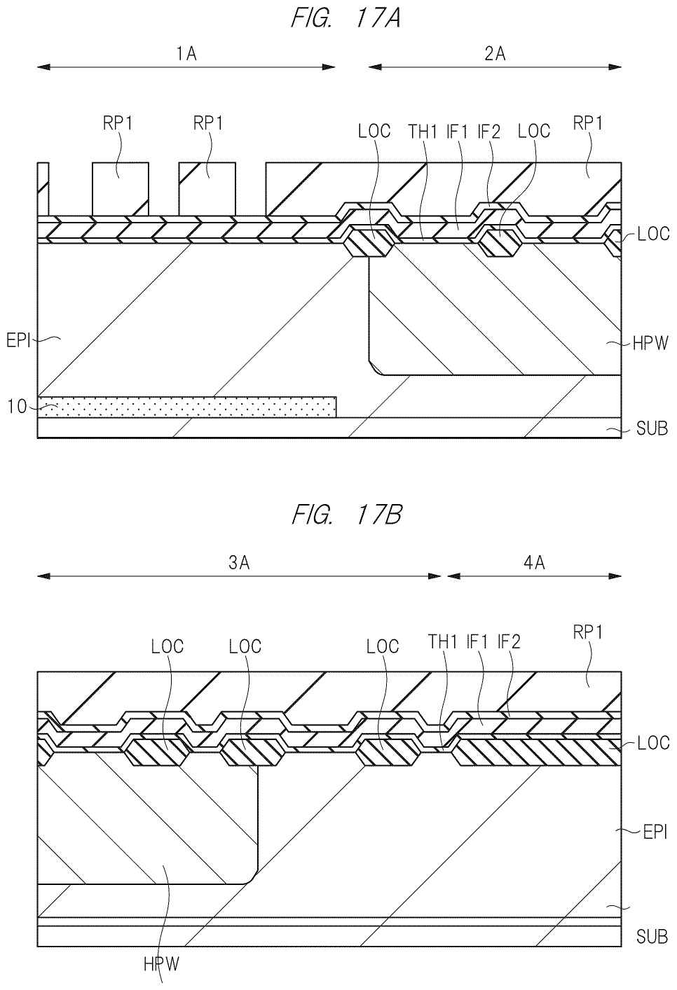

As illustrated in FIG. 17A and FIG. 17B, an insulating film IF1 made from a silicon nitride film is formed on the through film TH1 by, for example, the CVD method. Next, the insulating film IF2 made from a silicon oxide film is formed over the insulating film IF1 by, for example, the CVD method. Next, a resist pattern RP1 is formed on the insulating film IF2 so as to selectively open parts in the region 1A and to cover the region 2A, the region 3A, and the region 4A.

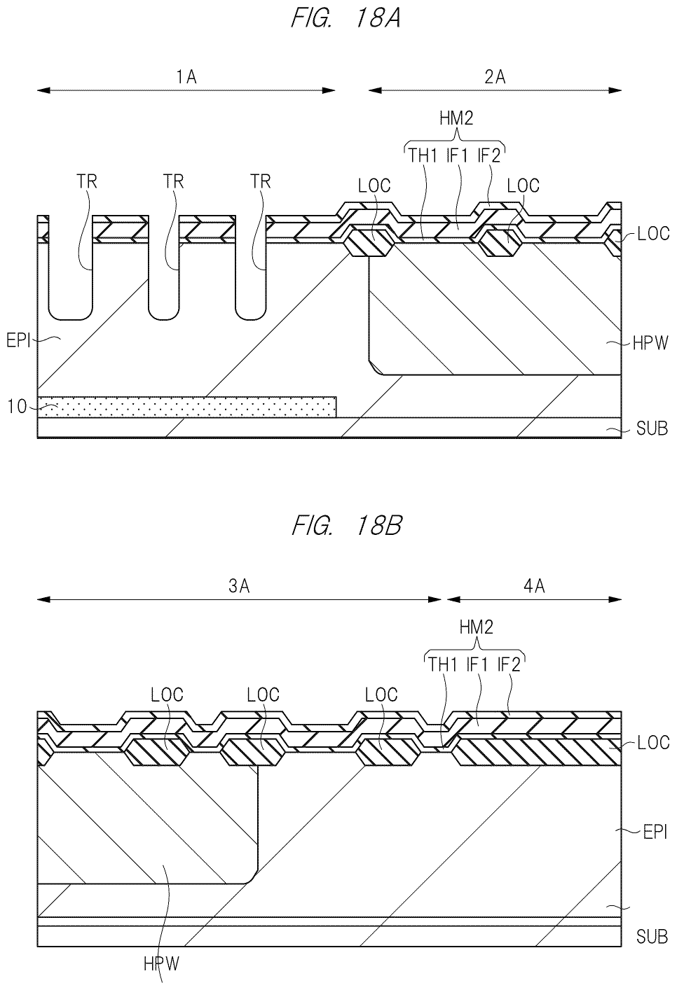

As illustrated in FIGS. 18A and 18B, anisotropic etching processing is performed using the resist pattern RP1 as a mask to pattern the through film TH1, the insulating film IF1, and the insulating film IF2. Accordingly, the hard mask HM2 is formed. Next, the resist pattern RP1 is removed by an ashing process. Thereafter, the anisotropic etching process is performed using the hard mask HM2 as a mask, thereby forming the trenches TR in the epitaxial layer EPI exposed from the hard mask HM2. Then, the epitaxial layer EPI (semiconductor substrate SUB) is cleaned. At this point, the insulating film IF2 is removed, but the through film TH1 and the insulating film IF1 are left as the hard mask HM2.

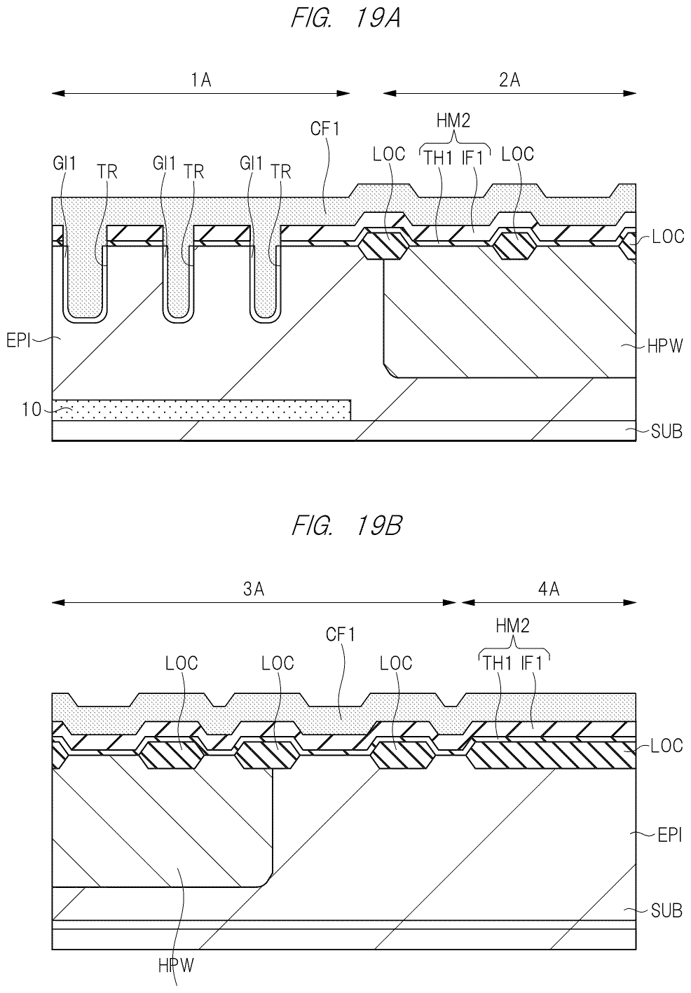

As illustrated in FIGS. 19A and 19B, inside the trenches TR, the gate insulating film GI1 is formed by the thermal oxidation treatment. Next, a conductive film CF1 is formed on the gate insulating film GI1 and the hard mask HM2 by, for example, the CVD method. The conductive film CF1 is a polycrystalline silicon film. Next, an impurity such as phosphorus (P) is ion-implanted into the conductive film CF1 to convert the conductive film CF1 into an n-type polycrystalline silicon film.

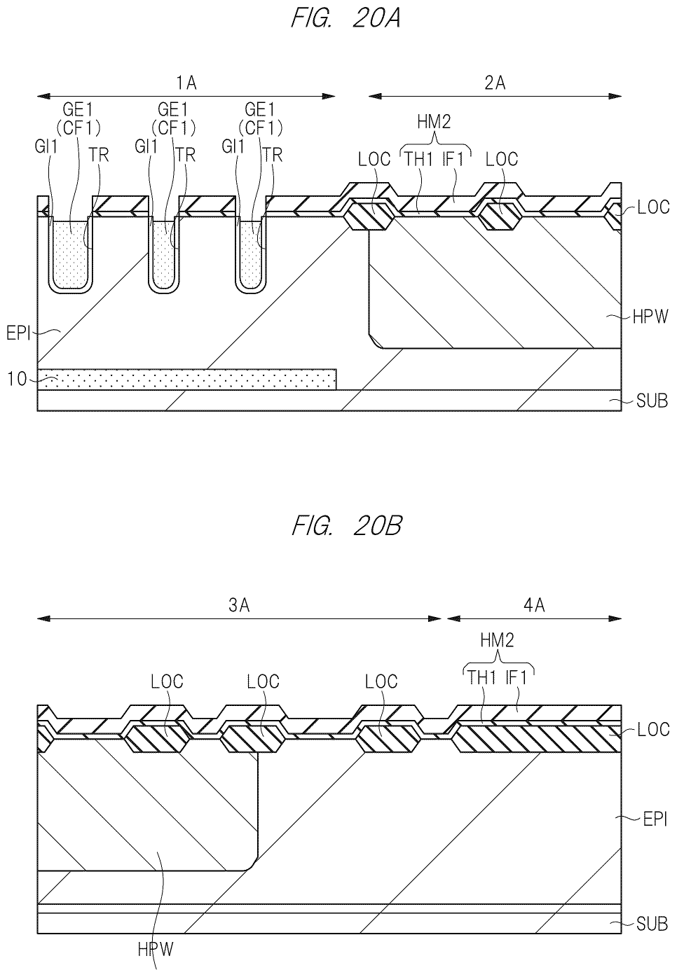

As illustrated in FIGS. 20A and 20B, the anisotropic etching process is performed on the conductive film CF1. Accordingly, the conductive film CF1 on the hard mask HM2 is removed, and the gate electrodes GE1 are formed inside the trenches TR so as to fill the inside of the trenches TR via the gate insulating film GI1.

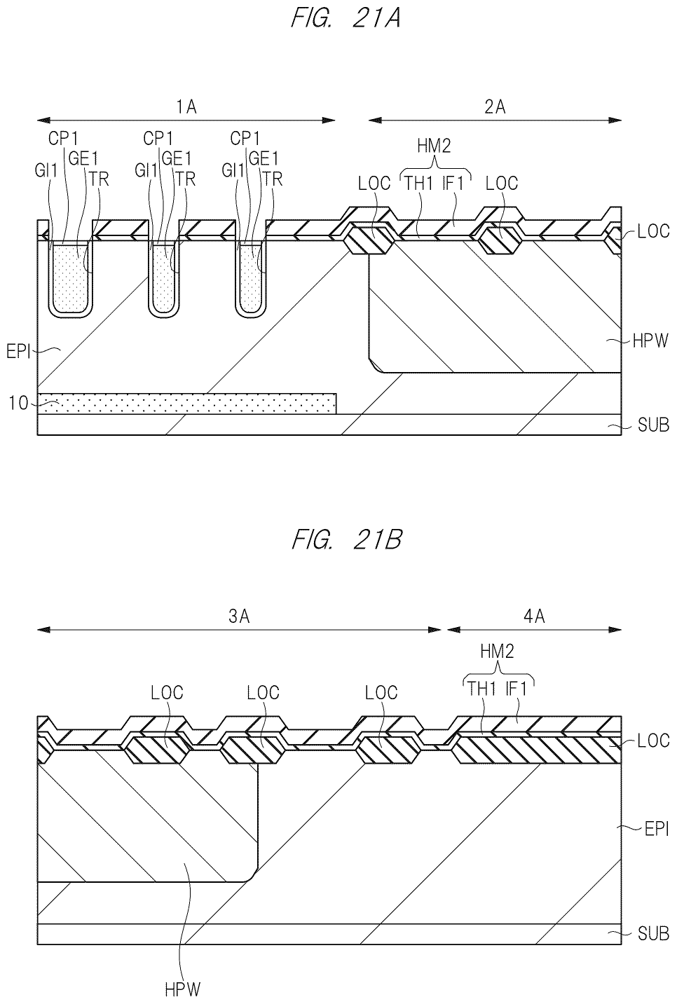

As illustrated in FIGS. 21A and 21B, a part of the gate electrode GE1 is oxidized by the thermal oxidation treatment. Accordingly, a cap film CP1 made of an insulating film is formed on the upper surface of the gate electrodes GE1. That is, the cap film CP1 is a silicon oxide film formed by thermally oxidizing the upper surface of the polycrystalline silicon film.

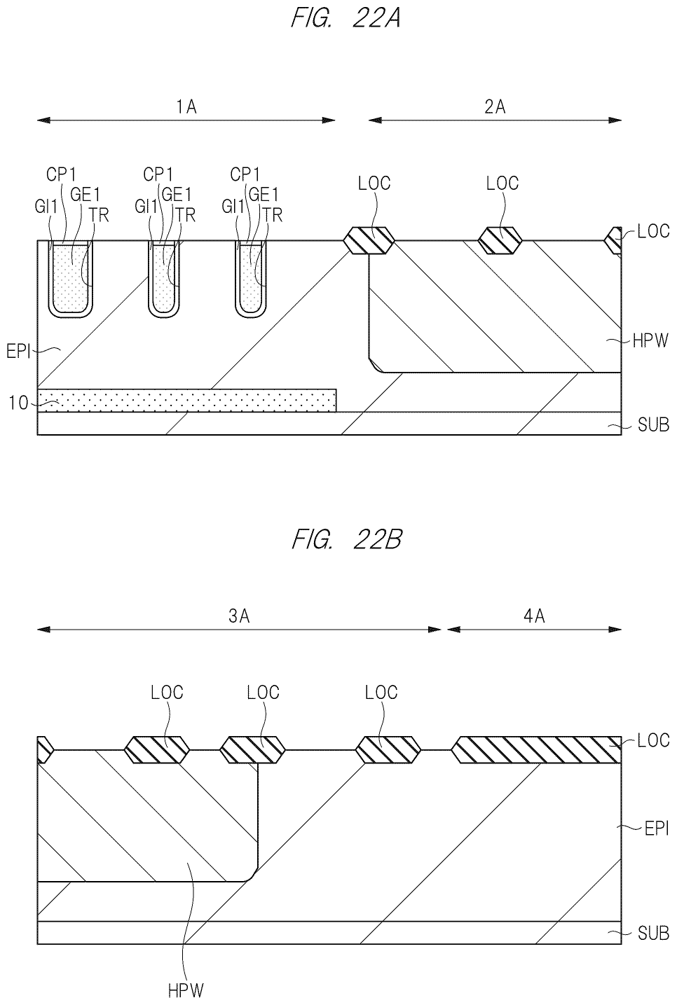

As illustrated in FIGS. 22A and 22B, the hard mask HM2 is removed. The insulating film IF1 is removed by the isotropic etching process using an aqueous solution containing phosphoric acid. Next, a cleaning step is performed using an aqueous solution containing hydrofluoric acid to remove the through film TH1.

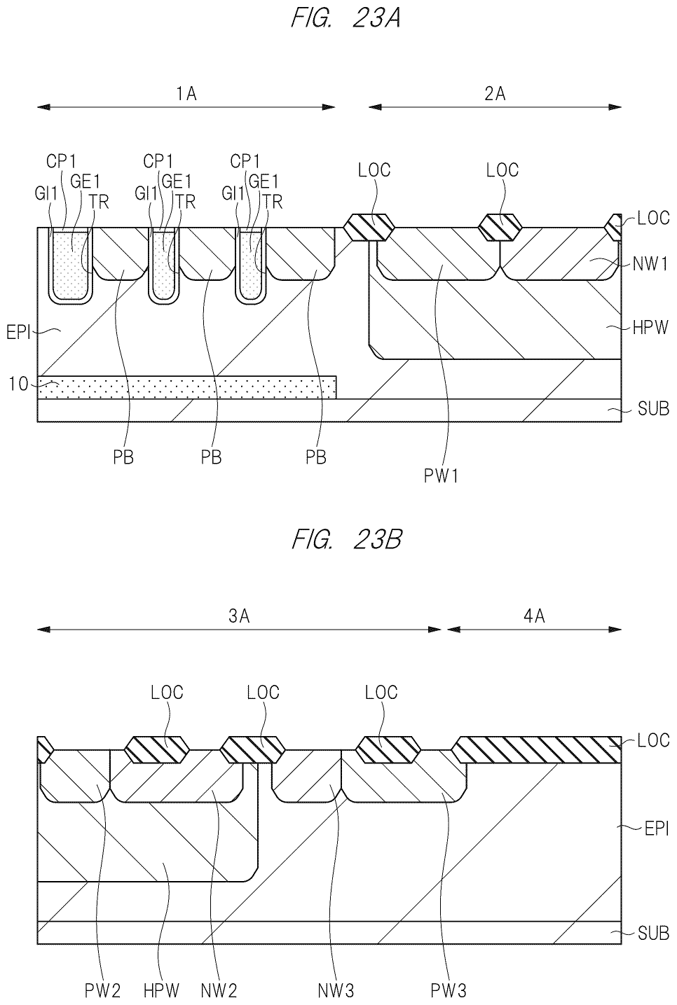

As illustrated in FIGS. 23A and 23B, photolithography and ion implantation are used to selectively form impurity regions in the epitaxial layer EPI in the region 1A, the region 2A, and the region 3A on the upper surface side of the epitaxial layer EPI.

In the region 1A, p-type body regions PB are formed in the epitaxial layer EPI so as to be shallower than the depth of the trenches TR. In the region 2A, a p-type well region PW1 and an n-type well region NW1 are formed in the epitaxial layer EPI. The well region PW1 and the well region NW1 are formed in the well region HPW. In the region 3A, a p-type well region PW2, an n-type well region NW2, a p-type well region PW3 and an n-type well region NW3 are formed in the epitaxial layer EPI. The well region PW2 and the well region NW2 are formed in the well region HPW.

Although not illustrated here, before ion implantation that selectively forms those impurity regions, a through film made from a silicon oxide film is formed on the upper surface of the epitaxial layer EPI. After ion implantation that selectively forms those impurity regions, the through film is removed by a cleaning step using an aqueous solution containing hydrofluoric acid.

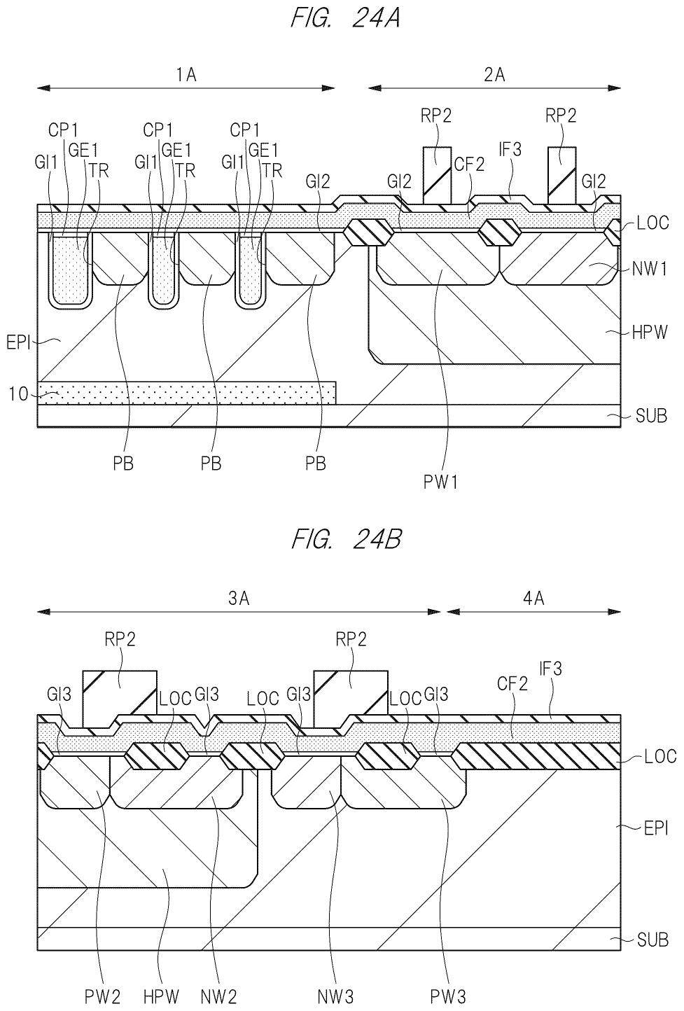

As illustrated in FIGS. 24A and 24B, a gate insulating film made from a silicon oxide film is formed on the upper surface of the epitaxial layer EPI by thermal oxidation treatment. Here, the gate insulating film formed on the well region PW1 and the well region NW1 in the region 2A is illustrated as a gate insulating film GI2. Further, the gate insulating film formed on the well region PW2, the well region NW2, the well region PW3, and the well region NW3 in the region 3A is illustrated as a gate insulating film GI3.

Next, a conductive film CF2 is formed on the gate insulating film G12, the gate insulating film GI3, and the cap film CP1. The material contained in the conductive film CF2 has a sheet resistance higher than the sheet resistance of the material contained in the conductive film CF1 (gate electrodes GE1). The conductive film CF2 is, for example, a laminated film of an n-type polycrystalline silicon film formed by the CVD method and a tungsten silicide film formed by the CVD method.

Next, an insulating film IF3 made from a silicon oxide film is formed on the conductive film CF2 by, for example, the CVD method. Next, a resist pattern RP2 is formed on the insulating film IF3 so as to selectively cover parts in the region 2A and parts in the region 3A.

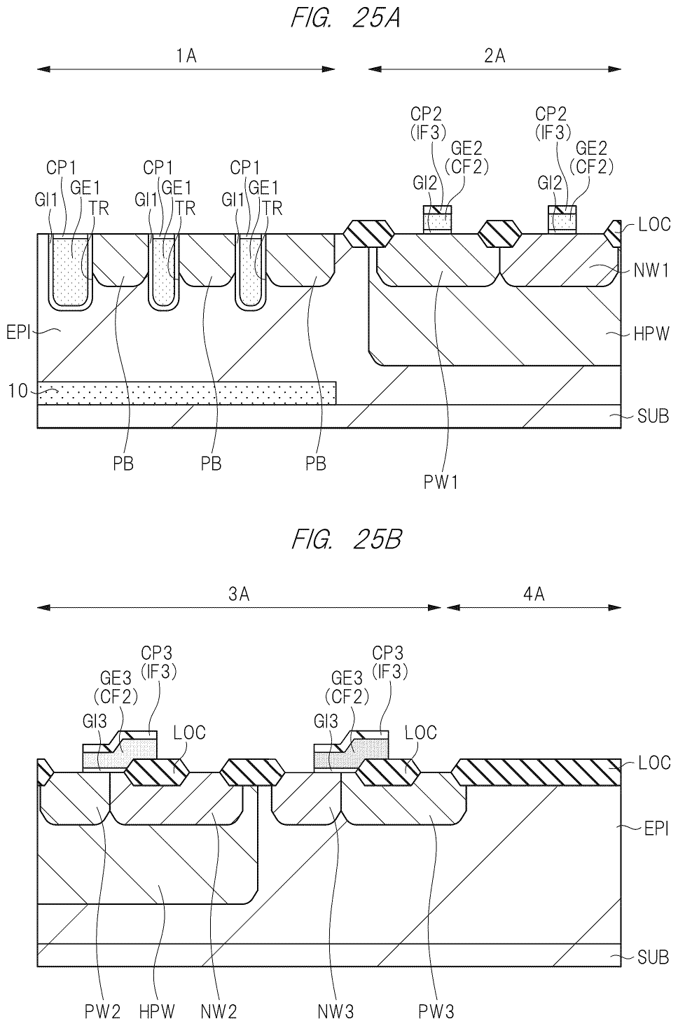

As illustrated in FIGS. 25A and 25B, the anisotropic etching process is performed using the resist pattern RP2 as a mask to pattern the insulating film IF3 and the conductive film CF2. Accordingly, the insulating film IF3 and the conductive film CF2 that are not covered with the resist pattern RP2 are removed. Then, on the upper surface of the epitaxial layer EPI in the region 2A, gate electrodes GE2 and a cap film CP2 are formed via the gate insulating film GI2. Further, on the upper surface of the epitaxial layer EPI in the region 3A, gate electrodes GE3 and a cap film CP3 are formed via the gate insulating film GI3.

Next, the resist pattern RP2 is removed by the ashing process. Thereafter, the gate insulating film GI2 and the gate insulating film GI3 exposed from the gate electrodes GE2 and the gate electrodes GE3 are removed by the cleaning step using an aqueous solution containing hydrofluoric acid.

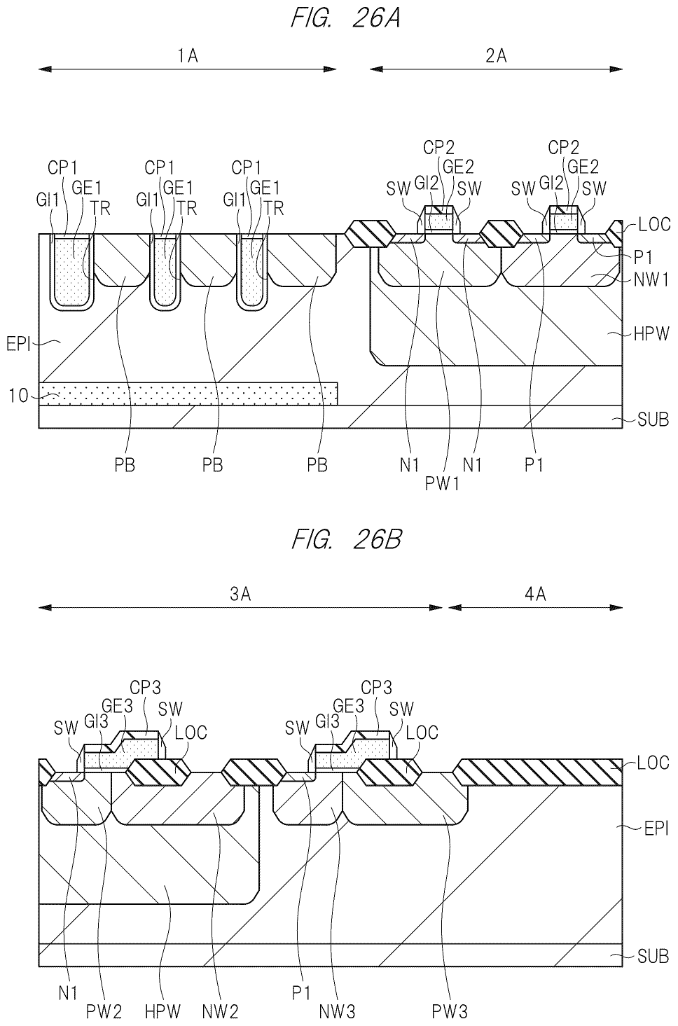

As illustrated in FIGS. 26A and 26B, photolithography and ion implantation are used to selectively form impurity regions in the epitaxial layer EPI in the region 2A and the region 3A on the upper surface side of the epitaxial layer EPI.

In the region 2A, n-type impurity regions N1 are formed in the well region PW1, and p-type impurity regions P1 are formed in the well region NW1. In the region 3A, an n-type impurity region N1 is formed in the well region PW2, and a p-type impurity region P1 is formed in the well region NW3.

Although not illustrated here, before ion implantation that selectively forms those impurity regions, a through film made from a silicon oxide film is formed on the upper surface of the epitaxial layer EPI. After ion implantation that selectively forms those impurity regions, the through film is removed by a cleaning step using an aqueous solution containing hydrofluoric acid.

Next, an insulating film such as a silicon oxide film is formed on the upper surface of the epitaxial layer EPI in the region 1A, the region 2A, the region 3A, and the region 4A by, for example, the CVD method. Next, the anisotropic etching process is performed on the insulating film to remove the insulating film on the upper surface of the epitaxial layer EPI, and sidewall spacers SW are formed on the respective side surfaces of the gate electrodes GE2 and the gate electrodes GE3.

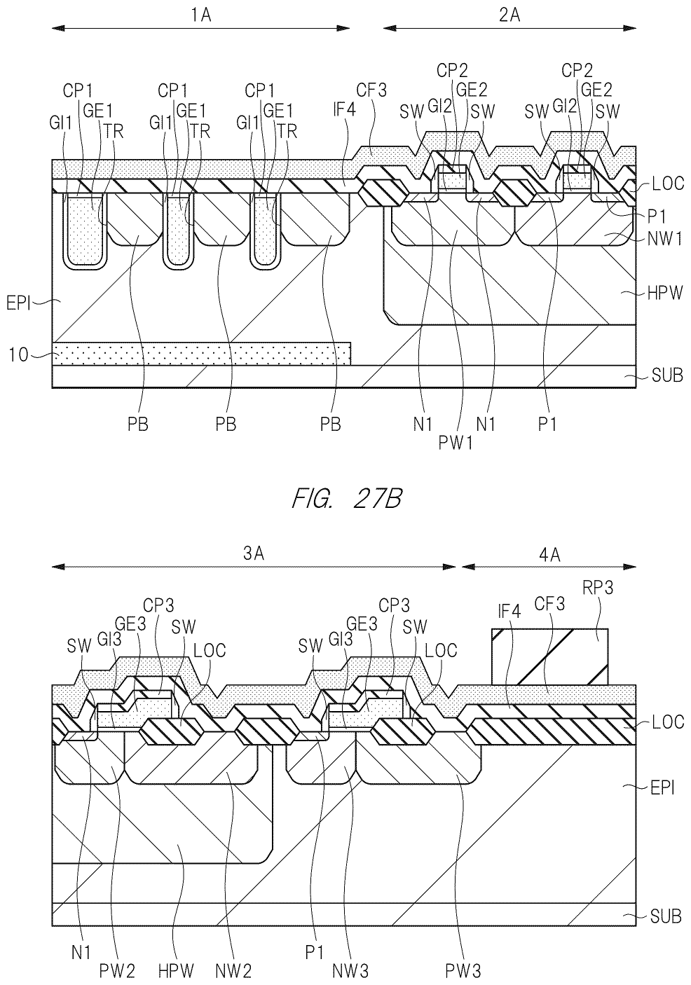

As illustrated in FIGS. 27A and 27B, an insulating film IF4 made from a silicon oxide film is formed on the upper surface of the epitaxial layer EPI by, for example, the CVD method so as to cover the gate electrodes GE1, GE2, and GE3 and the element isolation portions LOC.

Next, a conductive film CF3 is formed on the insulating film IF4 by, for example, the CVD method. The material contained in the conductive film CF3 has a sheet resistance higher than the sheet resistance of the material contained in the conductive films CF1 and CF2 (gate electrodes GE1, GE2, and GE3). The conductive film CF3 is a polycrystalline silicon film. Subsequently, an impurity such as boron (B) is ion-implanted into the conductive film CF3 to convert the conductive film CF3 into a p-type polycrystalline silicon film. Thereafter, a resist pattern RP3 is formed on the conductive film CF3 so as to selectively cover a part in the region 4A.

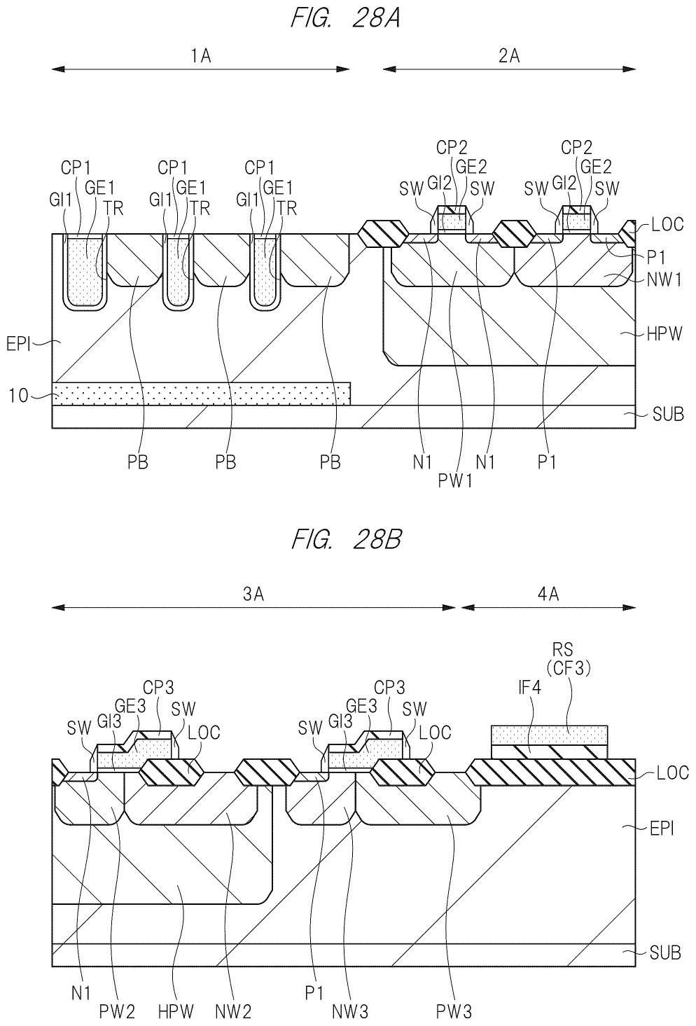

As illustrated in FIGS. 28A and 28B, the anisotropic etching process is performed using the resist pattern RP3 as a mask to pattern the conductive film CF3. Accordingly, the resistive element RS is formed. Next, the resist pattern RP3 is removed by the ashing process. Then, a cleaning step is performed using an aqueous solution containing hydrofluoric acid to remove the insulating film IF4 exposed from the resistive element RS.

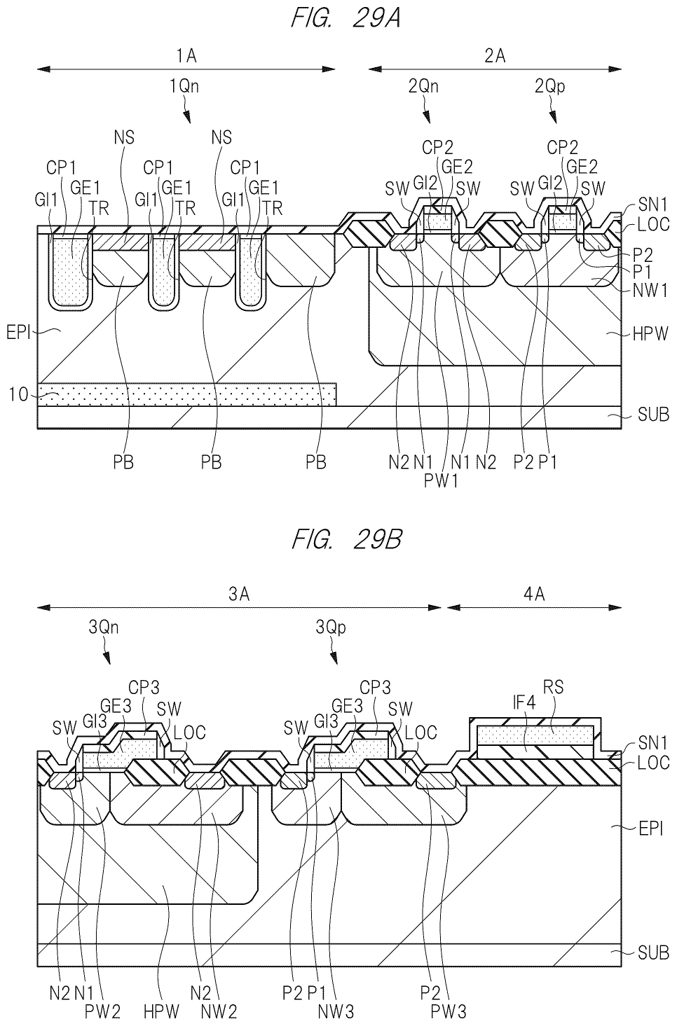

As illustrated in FIGS. 29A and 29B, photolithography and ion implantation are used to selectively form impurity regions in the epitaxial layer EPI in the region 1A, the region 2A, and the region 3A on the upper surface side of the epitaxial layer EPI.

In the region 1A, n-type source regions NS are formed in the body regions PB. In the region 2A, n-type impurity regions N2 are formed in the well region PW1, and p-type impurity regions P2 are formed in the well region NW1. Accordingly, in the region 2A, the source region and the drain region of the MOSFET 2Qn including the impurity regions N1 and N2 are formed, and the source region and the drain region of the MOSFET 2Qp including the impurity regions P1 and P2 are formed.

In the region 3A, an n-type impurity region N2 is formed in the well region PW2, an n-type impurity region N2 is formed in the well region NW2, a p-type impurity region P2 is formed in the well region NW3, and a p-type impurity region P2 is formed in the well region PW3.

Accordingly, in the region 3A, the source region of the LDMOSFET 3Qn including the impurity regions N1 and N2 is formed, and the drain region of the LDMOSFET 3Qn including the well region NW2 and the impurity region N2 is formed. Further, in the region 3A, the source region of the LDMOSFET 3Qp including the impurity regions P1 and P2 is formed, and the drain region of the LDMOSFET 3Qp including the well region PW3 and the impurity region P2 is formed.

Although not illustrated here, before ion implantation that selectively forms those impurity regions, a through film made from a silicon oxide film is formed on the upper surface of the epitaxial layer EPI. After ion implantation of that selectively forms those impurity regions, the through film may be removed by a cleaning step using an aqueous solution containing hydrofluoric acid, but the through film may also be left in place.

Next, heat treatment is performed on the source region and the drain region of each of the power transistor 1Qn, the MOSFETS 2Qn and 2Qp, and the LDMOSFETs 3Qn and 3Qp. The heat treatment is performed in a nitrogen atmosphere under a condition of, for example, 850° C. and 20 minutes. This heat treatment activates the impurities contained in the source region and the drain region of each of the power transistor 1Qn, the MOSFETs 2Qn and 2Qp, and the LDMOSFETs 3Qn and 3Qp.

Through the above manufacturing steps, the basic structures of the power transistor 1Qn, MOSFETs 2Qn and 2Qp, and LDMOSFETS 3Qn and 3Qp are obtained.

Next, across the region 1A, the region 2A, the region 3A, and the region 4A, a silicon nitride film SN1 is formed by, for example, the CVD method on the upper surface of the epitaxial layer EPI so as to cover the gate electrodes GE1, GE2, and GE3 and the resistive element RS. The thickness of the silicon nitride film SN1 is, for example, 10 nm or more and 20 nm or less.

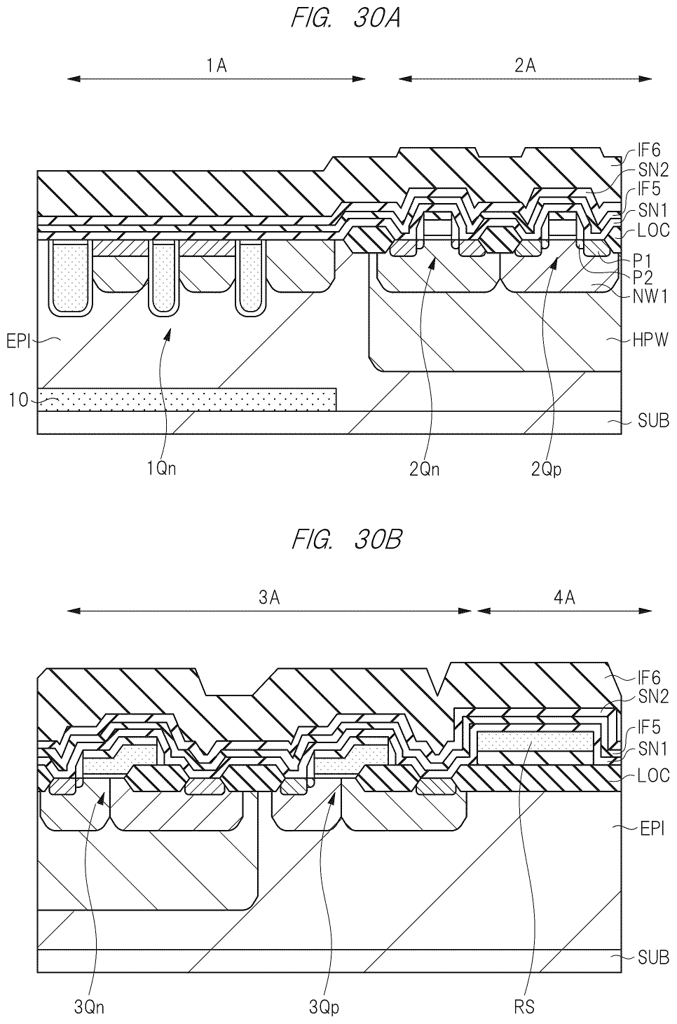

As illustrated in FIGS. 30A and 30B, an insulating film IF5 made from a silicon oxide film, a silicon nitride film SN2, and an insulating film IF6 made from a silicon oxide film are successively formed on the silicon nitride film SN1 by, for example, the CVD method. The thickness of the insulating film IF5 is, for example, 80 nm or more and 120 nm or less. The thickness of the silicon nitride film SN2 is, for example, 120 nm or more and 160 nm or less. The thickness of the insulating film IF6 is, for example, 1000 nm or more and 1400 nm or less.

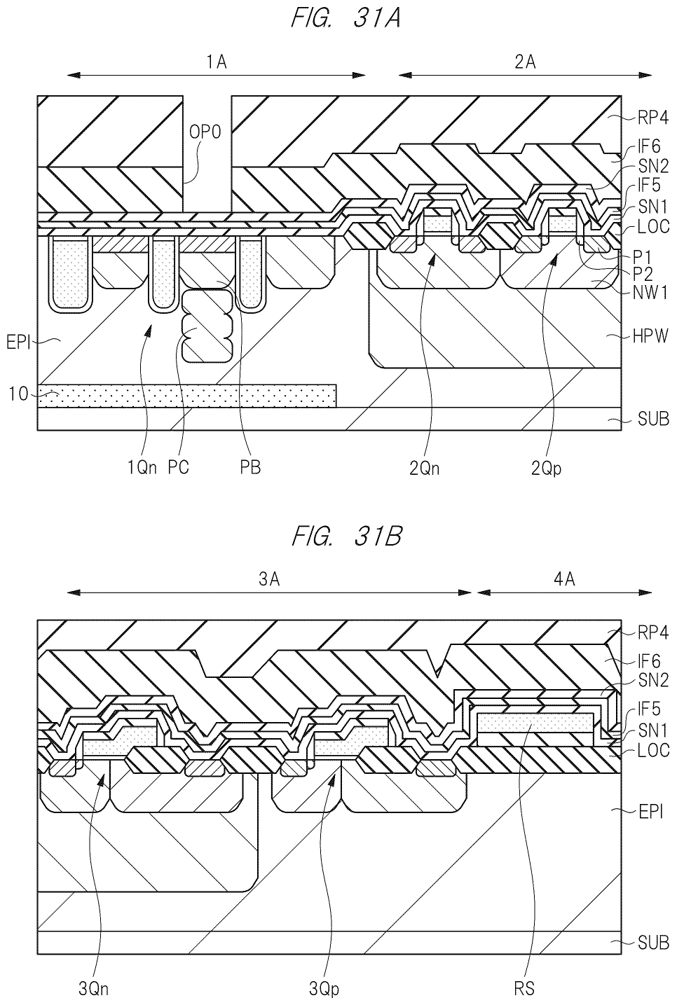

As illustrated in FIGS. 31A and 31B, a resist pattern RP4 is formed on the insulating film IF6 so as to selectively open a part in the region 1A. Next, the anisotropic etching process is performed using the resist pattern RP4 as a mask, thereby forming an opening OP0 in the insulating film IF6 located on the body region PB. At this point, the silicon nitride film SN2 functions as an etching stopper.

Subsequently, ions are implanted in the opening OP0 so as to pass through the silicon nitride film SN1, the insulating film IF5, and the silicon nitride film SN2. Accordingly, a p-type column region PC is formed in the epitaxial layer EPI located under the body region PB.

In this ion implantation, boron (B), for example, is used as the impurity, and the implantation is implemented in a plurality of times with varying implantation energies. Then, the resist pattern RP4 is removed by the ashing process.

Here, it is desirable to form the column region PC after the heat treatment for activating the impurities contained in the source region and the drain region of each of the power transistor 1Qn, the MOSFETs 2Qn and 2Qp, and the LDMOSFETs 3Qn and 3Qp.

If the above-mentioned heat treatment for activation is performed after the formation of the column region PC, the impurities contained in the column region PC may diffuse, causing the column region PC to widen. If the position of the column region PC widens too much from the design value, the on-resistance of the power transistor 1Qn may increase. In addition, since the diffusion position of the column region PC is difficult to control through heat treatment, there is a risk that the spread of the depletion layer may vary and the expected breakdown voltage may not be obtained. Therefore, in the first embodiment, the column region PC is formed after the above-mentioned heat treatment for activation.

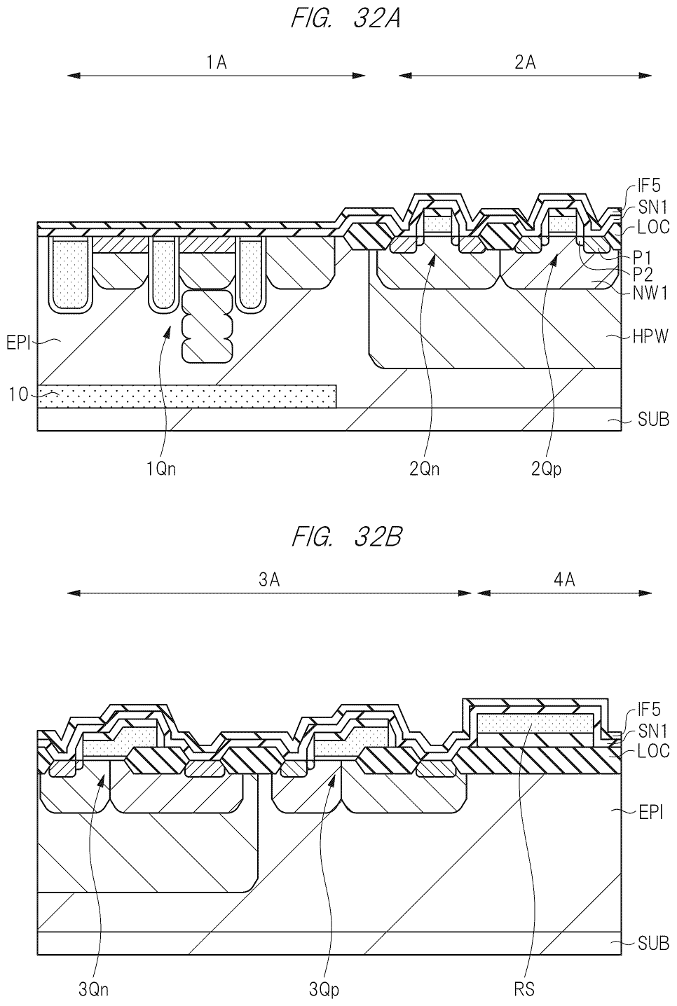

As illustrated in FIGS. 32A and 32B, the isotropic etching process s performed using an aqueous solution containing hydrofluoric acid to remove the insulating film IF6, with the silicon nitride film SN2 serving as an etching stopper. Next, the isotropic etching process is performed using an aqueous solution containing phosphoric acid to remove the silicon nitride film SN2, with the insulating film IF5 serving as an etching stopper. Since the insulating film IF5 is formed between the silicon nitride film SN1 and the silicon nitride film SN2, the silicon nitride film SN1 can be prevented from being removed when the silicon nitride film SN2 is removed. Thereafter, the insulating film IF5 may be removed by the isotropic etching process using an aqueous solution containing hydrofluoric acid, or the insulating film IF5 may be left as a part of the interlayer insulating film IL1. Here, the case where the insulating film IF5 is left will be illustrated.

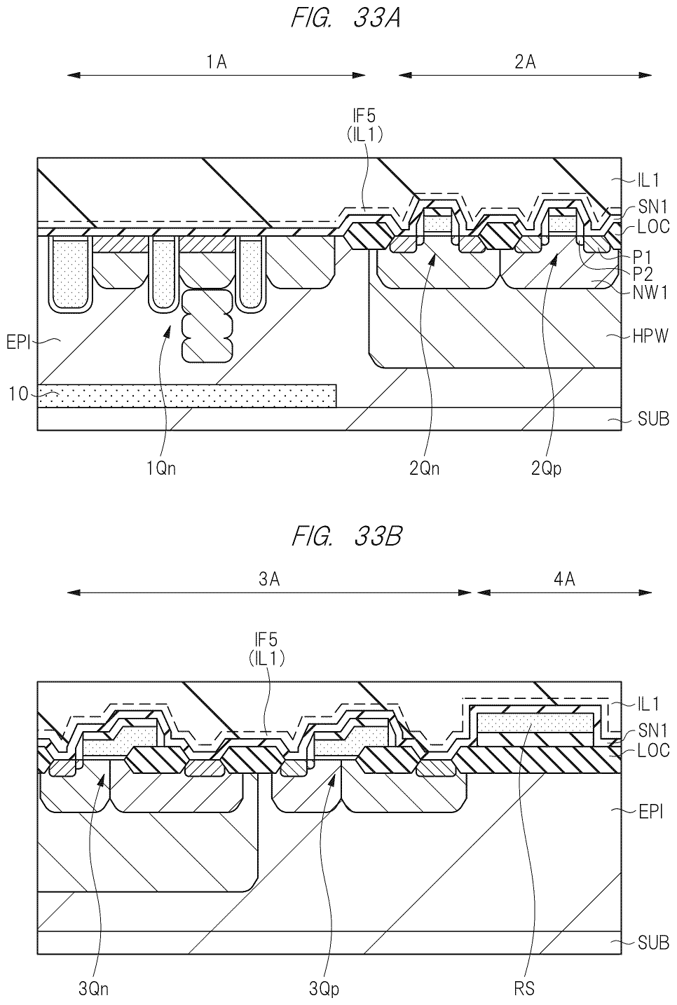

As illustrated in FIG. 33A and 33B, an interlayer insulating film IL1 is formed on the upper surface of the epitaxial layer EPI across the region 1A, the region 2A, the region 3A, and the region 4A so as to cover the gate electrodes GE1, GE2, GE3 and the resistive element RS.

First, a silicon oxide film is formed on the silicon nitride film SN1 by, for example, the CVD method. Next, a BPSG film is formed on the silicon oxide film by, for example, a coating method. Next, the heat treatment is performed on the BPSG film. The heat treatment is performed in a nitrogen atmosphere under a condition of, for example, 850° C. and 20 minutes. This heat treatment may cause boron or phosphorus to diffuse from the BPSG film to the epitaxial layer EPI side, but the silicon oxide film can prevent such diffusion. When the insulating film IF5 is left, the formation of the silicon oxide film is not essential.

Thereafter, the interlayer insulating film IL1 is polished by a polishing process using a Chemical Mechanical Polishing (CMP) method. Accordingly, the upper surface of the interlayer insulating film IL1 is planarized.

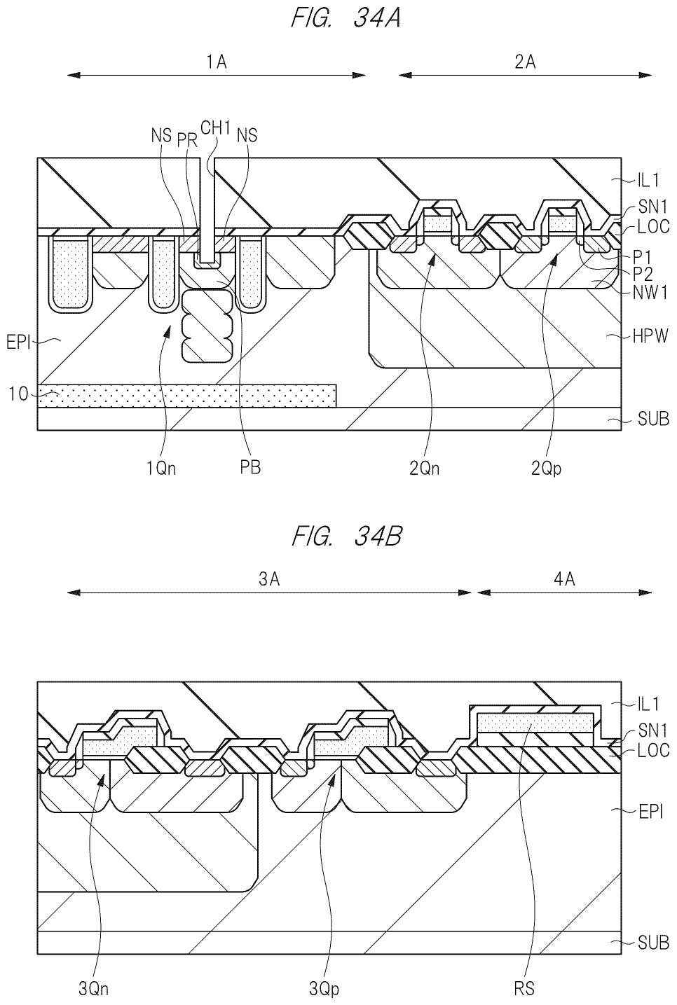

As illustrated in FIGS. 34A and 34B, a hole CH1 is formed in the interlayer insulating film IL1, the silicon nitride film SN1, the source region NS, and the body region PB in the region 1A by photolithography and the anisotropic etching process. The bottom of the hole CH1 is located inside the body region PB.

In etching of the interlayer insulating film IL1, the silicon nitride film SN1 functions as an etching stopper. Thereafter, the gas and other conditions are changed, and the silicon nitride film SN1 and the epitaxial layer EPI are etched in sequence. Since the etching process is stopped once at the silicon nitride film SN1, it is easier to uniform the depth of the plurality of holes CH1 within the wafer surface.

Next, for example, boron (B) is introduced into the body region PB at the bottom of the hole CH1 by ion implantation to form a p-type high-concentration diffusion region PR.

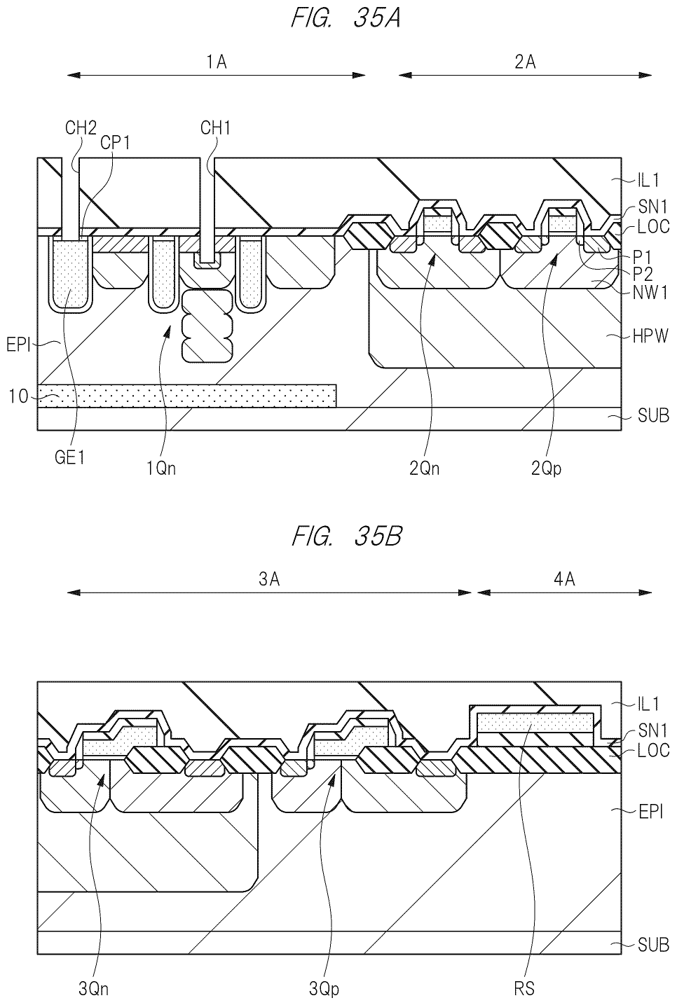

As illustrated in FIGS. 35A and 35B, a hole CH2 is formed in the interlayer insulating film IL1, the silicon nitride film SN1 and the cap film CP1 in the region 1A by photolithography and the anisotropic etching process. The hole CH2 reaches the gate electrode GE1. As in the manufacturing step of the hole CH1, in etching of the interlayer insulating film IL1, the silicon nitride film SN1 functions as an etching stopper.

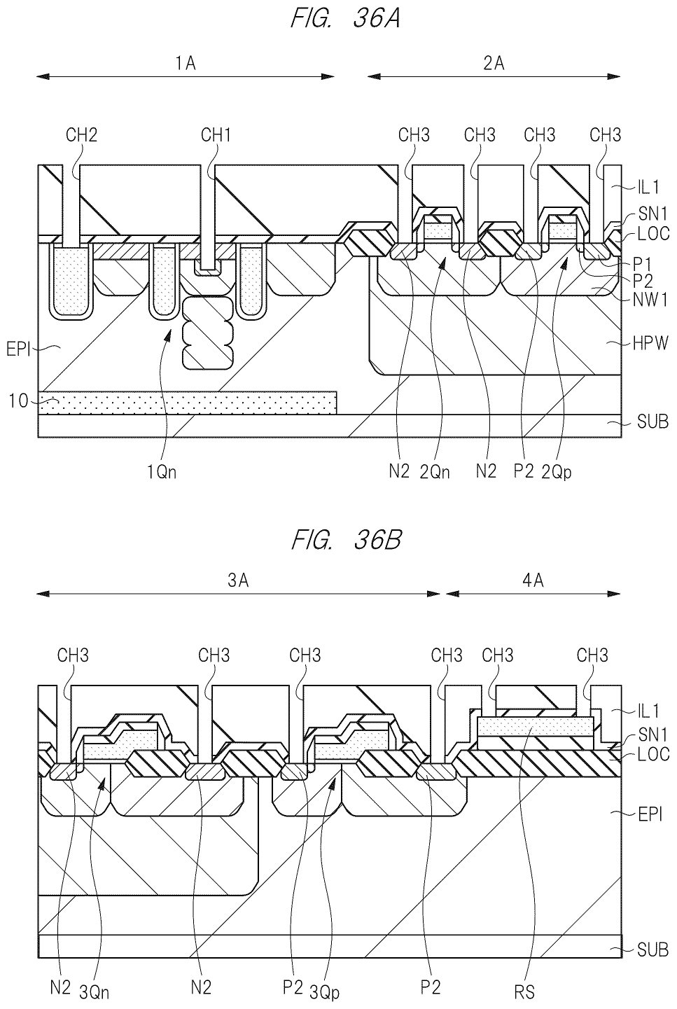

As illustrated in FIGS. 36A and 36B, hole CH3 are formed in the interlayer insulating film IL1 and the silicon nitride film SN1 across the region 2A the region 3A, the region 4A by photolithography and the anisotropic etching process. In the region 2A, the plurality of holes CH3 reaches the source region and the drain region of each of the MOSFETs 2Qn and 2Qp. In the region 3A, the plurality of holes CH3 reaches the source region and the drain region of each of the LDMOSFETs 3Qn and 3Qp. In the region 4A, the plurality of holes CH3 reaches the resistive element RS. As in the manufacturing step of the hole CH1, in etching of the interlayer insulating film IL1, the silicon nitride film SN1 functions as an etching stopper.

Although not illustrated here, the holes CH3 reaching the gate electrodes GE2 and GE3 are also formed in the interlayer insulating film IL1 and the silicon nitride film SN1.

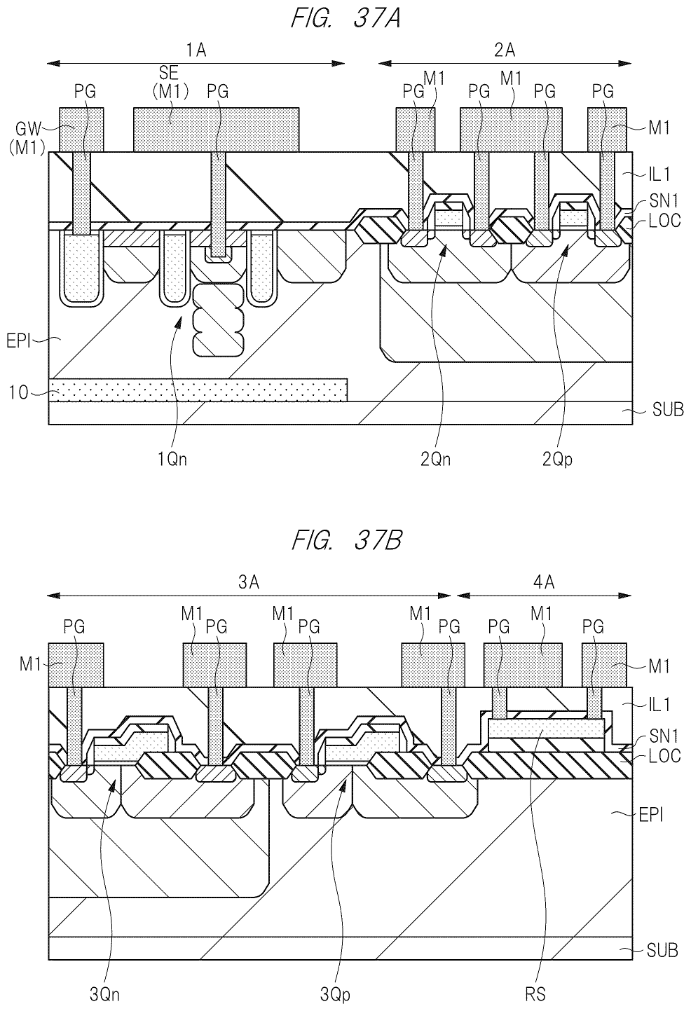

As illustrated in FIG. 37A and FIG. 37B, a plug PG is formed inside each of the holes CH1, CH2, and CH3. First, a barrier metal film is formed inside each of the holes CH1, CH2, and CH3 and on the interlayer insulating film IL1 by, for example, a sputtering method. Next, a conductive film is formed by, for example, the CVD method on the barrier metal film so as to fill the inside of each of the holes CH1, CH2, and CH3. Next, for example, the anisotropic etching process is performed to remove the barrier metal film and the conductive film formed outside each of the holes CH1, CH2, and CH3. Accordingly, the plugs PG are formed in the interlayer insulating film IL1. The barrier metal film is, for example, a laminated film of a titanium film and a titanium nitride film. The conductive film is, for example, a tungsten film.

Then, a first barrier metal film, a conductive film, and a second barrier metal film are formed in this order on the interlayer insulating film IL1 by, for example, the sputtering method or the CVD method. Next, the first barrier metal film, the conductive film, and the second barrier metal film are patterned to form wirings M1 connected to the plugs PG on the interlayer insulating film IL1. The first barrier metal film is, for example, a laminated film of a titanium film and a titanium nitride film. The conductive film is, for example, an aluminum alloy film with added copper or silicon, or an aluminum film. The second barrier metal film is, for example, a laminated film of a titanium film and a titanium nitride film.

Thereafter, the structure illustrated in FIGS. 8 and 9 is obtained through the following manufacturing steps.

An interlayer insulating film IL2 is formed on the interlayer insulating film IL1 so as to cover the wirings M1. To form the interlayer insulating film IL2, first, a first silicon oxide film is formed on the interlayer insulating film IL1 by, for example, a high density plasma CVD (HDP-CVD) method. Next, a second silicon oxide film is formed on the first silicon oxide film by, for example, the CVD method. Next, the first silicon oxide film and the second silicon oxide film are planarized by a polishing process using a CMP method. Accordingly, an interlayer insulating film IL2 including the first silicon oxide film and the second silicon oxide film is formed.

Incidentally, a hydrogen alloy process may be performed after the formation of the interlayer insulating film IL2 and before the formation of the vias V1, which will be described later. The hydrogen alloy process is a heat treatment performed in a hydrogen atmosphere under conditions such as 400° C. and 20 minutes. Through the hydrogen alloy process, dangling bonds near the upper surface of the epitaxial layer EPI can be terminated, thereby improving the variation in the threshold voltage of the power transistor 1Qn.

Subsequently, vias V1 are formed in the interlayer insulating film IL2 so as to be connected to the wirings M1. To form the vias V1, first, contact holes are formed in the interlayer insulating film IL2 by photolithography and the anisotropic etching process. Next, a barrier metal film is formed inside the contact holes and on the interlayer insulating film IL2 by, for example, the CVD method. Then, a conductive film is formed on the barrier metal film by, for example, the CVD method so as to fill the inside of the contact holes.

Thereafter, for example, the anisotropic etching process is performed to remove the barrier metal film and the conductive film formed outside the contact holes. Accordingly, the vias V1 are formed in the interlayer insulating film IL2. The barrier metal film is, for example, a titanium nitride film. The conductive film is, for example, a tungsten film.

Subsequently, wirings M2 are formed on the interlayer insulating film IL2 so as to be connected to the vias V1. Then, an interlayer insulating film IL3 is formed on the interlayer insulating film IL2 so as to cover the wirings M2. Subsequently, vias V2 are formed in the interlayer insulating film IL3 so as to be connected to the wirings M2. The manufacturing step for the wirings M2, the interlayer insulating film IL3, and the vias V2 can be performed in the same manner as the manufacturing step for the wirings M1, the interlayer insulating film IL2, and the vias V1.

Incidentally, the hydrogen alloy process may be performed under the same conditions as described above after the formation of the interlayer insulating film IL3 and before the formation of the vias V2. The hydrogen alloy process may be performed only after the formation of the interlayer insulating film IL2, or only after the formation of the interlayer insulating film IL3, or may be performed after both of the cases.

Subsequently, wirings M3 are formed on the interlayer insulating film IL3 so as to be connected to the vias V2. To form the wirings M3, first, a barrier metal film and a conductive film are successively formed on the interlayer insulating film IL3 by, for example, the sputtering method or the CVD method. Next, the barrier metal film and the conductive film are patterned to form the wirings M3 on the interlayer insulating film IL3. The barrier metal film is a titanium tungsten film. The conductive film is an aluminum alloy film with added copper or silicon, or an aluminum film.

Then, a protective film PVF is formed on the interlayer insulating film IL3 so as to cover the wirings M3 by, for example, a coating method. The protective film PVF is, for example, a polyimide film. Thereafter, openings (not illustrated) are formed in the protective film PVF on the wirings M3 so that parts of the wirings M3 are exposed. The parts of the wirings M3 exposed in the openings constitute a source pad PADS or pads PAD for connection to an external connection member (see FIG. 6).

Thereafter, the lower surface of the semiconductor substrate SUB is polished as necessary.

Subsequently, for example, arsenic (As) is introduced into the lower surface of the semiconductor substrate SUB by ion implantation to form an n-type drain region ND. Next, the drain electrode DE is formed on the lower surface of the semiconductor substrate SUB by the sputtering method.

In this manner, the semiconductor device 100 according to the first embodiment is manufactured.

### Characteristics of First Embodiment

One of the characteristics of the first embodiment is that, for example, as illustrated in FIGS. 7A and 7B, a semiconductor region 10 having an impurity concentration higher than the impurity concentration of the epitaxial layer EPI is provided inside the epitaxial layer EPI in the region 1A, among the region 1A, the region 2A, the region 3A, and the region 4A. This allows the on-resistance of the power transistor 1Qn formed in the region 1A to be reduced. This is because, although the on-resistance of the power transistor 1Qn depends on the impurity concentration of the epitaxial layer EPI, a high-concentration semiconductor region 10 having low resistance is formed inside the epitaxial layer EPI.

Meanwhile, another characteristic of the first embodiment is that the above-mentioned semiconductor region 10 is not formed inside the epitaxial layer EPI in the region 2A, the region 3A, and the region 4A. This allows the breakdown voltage of the MOSFETs 2Qn and 2Qp formed in the region 2A and the LDMOSFETS 3Qn and 3Qp formed in the region 3A to be higher than the avalanche breakdown voltage of the power transistor 1Qn. This is because the semiconductor region 10 having an impurity concentration higher than the impurity concentration of the epitaxial layer EPI is to be the cause of a decrease in the breakdown voltage.

In this manner, in a semiconductor device (IPD) in which the power transistor 1Qn, the MOSFETs 2Qn, 2Qp, and the LDMOSFETS 3Qn, 3Qp are mounted on a single semiconductor substrate, it is possible to achieve both a reduction in the on-resistance of the power transistor 1Qn and an improvement in the breakdown voltage of the MOSFETs 2Qn, 2Qp, and the LDMOSFETs 3Qn, 3Qp.

In particular, the first embodiment is characterized in that the semiconductor region 10 is formed inside the epitaxial layer EPI in the region 1A by utilizing the difference in thermal diffusion coefficient between phosphorus and arsenic, which are n-type impurities. That is, in the first embodiment, for example, as illustrated in FIGS. 12A and 12B, a semiconductor substrate SUB into which arsenic is introduced is prepared, and as illustrated in FIGS. 13A and 13B, phosphorus is introduced into the region 1A of the semiconductor substrate SUB to form a semiconductor region 10A. Thereafter, as illustrated in FIGS. 14A and 14B, an epitaxial layer EPI is formed on the semiconductor substrate SUB by using the epitaxial growth method.

At this point, arsenic introduced into the semiconductor substrate SUB is thermally diffused into the epitaxial layer EPI, and phosphorus introduced into the semiconductor region 10A is also thermally diffused into the epitaxial layer EPI. Here, the thermal diffusion coefficient of phosphorus is greater than the thermal diffusion coefficient of arsenic. For this reason, phosphorus diffuses to a shallower position in the epitaxial layer EPI than arsenic. As a result, the semiconductor region 10 illustrated in FIG. 14A is formed. That is, the first embodiment is characterized by the method of manufacturing that forms the semiconductor region 10 in the epitaxial layer EPI by utilizing the fact that phosphorus has a thermal diffusion coefficient greater than that of arsenic. According to the first embodiment having such characteristics, the semiconductor region 10 can be automatically formed by the heat treatment applied when forming the epitaxial layer EPI on the semiconductor substrate SUB.

### Second Embodiment

A method of manufacturing the semiconductor region 10 is not limited to the method of manufacturing in the first embodiment that utilizes the difference in thermal diffusion coefficient between phosphorus and arsenic, and can also be implemented by, for example, a method of manufacturing described below.

First, as illustrated in FIG. 12A and FIG. 12B, a semiconductor substrate SUB is prepared. Arsenic (As), which is an n-type impurity, is introduced into the semiconductor substrate SUB.

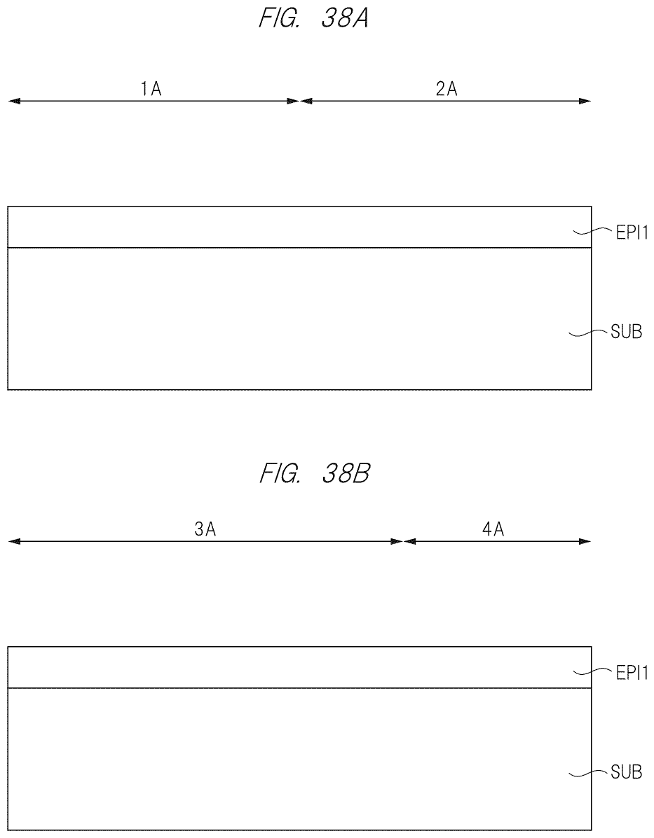

Next, as illustrated in FIGS. 38A and 38B, an epitaxial layer EPI1 having a first impurity concentration into which phosphorus, which is an n-type impurity, is introduced is formed on the semiconductor substrate SUB by epitaxial growth. That is, across a region 1A, a region 2A, a region 3A and a region 4A, the epitaxial layer EPI1 is formed on the semiconductor substrate SUB.

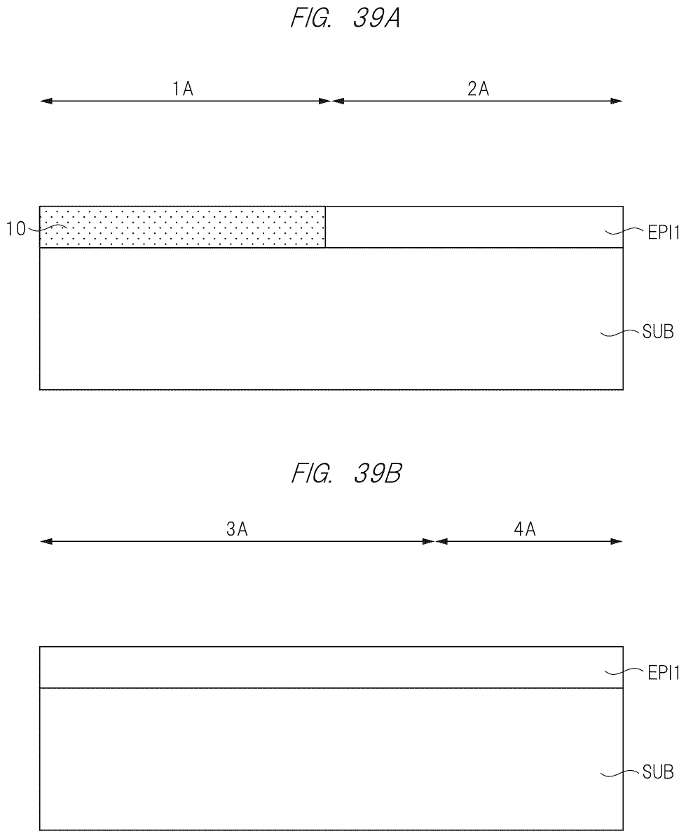

Thereafter, as illustrated in FIGS. 39A and 39B, phosphorus which is an n-type impurity is introduced into the region 1A of the epitaxial layer EPI1, thereby making the impurity concentration in the region 1A higher than the above-mentioned first impurity concentration. Accordingly, the semiconductor region 10, which has an impurity concentration higher than the first impurity concentration of the epitaxial layer EPI1 can be formed in the region 1A of the epitaxial layer EPI1.

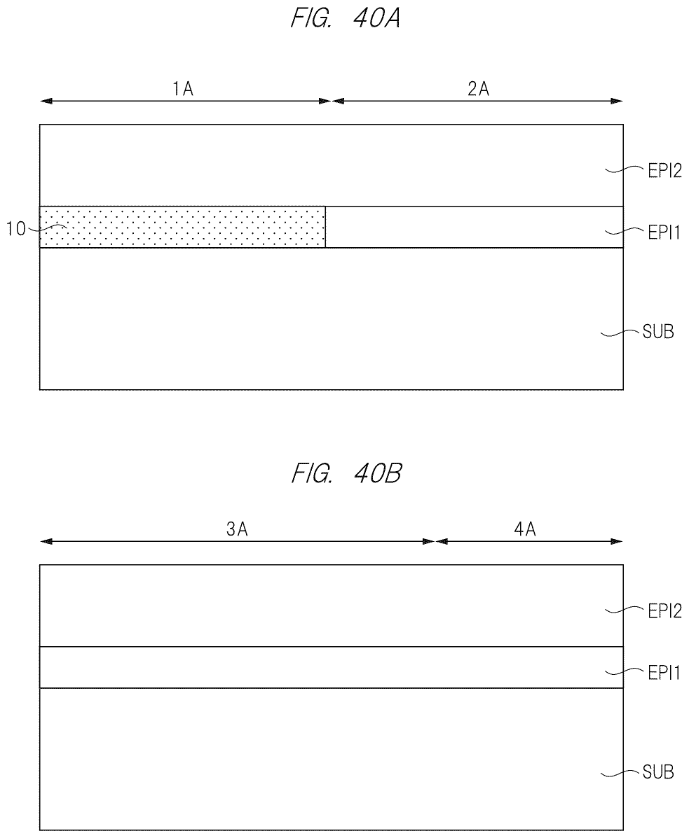

Subsequently, as illustrated in FIGS. 40A and 40B, an epitaxial layer EPI2 into which phosphorus, which is an n-type impurity, is introduced, is formed by epitaxial growth on the epitaxial layer EPI1 in which the semiconductor region 10 is formed.

Accordingly, for example, the semiconductor region 10 illustrated in the first modification of the basic concept can be formed (see FIG. 2). The subsequent steps are the same as the manufacturing steps of the semiconductor device in the first embodiment. The second modification (see FIG. 3), the third modification (see FIG. 4), and the fourth modification (see FIG. 5) of the basic concept can also be formed by applying the manufacturing method of the semiconductor region 10 in the second embodiment.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

In the above-described embodiments, a configuration example (first example) in which n-type impurities are introduced into the semiconductor substrate SUB, the epitaxial layer EPI, and the semiconductor region 10 has been described. However, the technical concept of the embodiments is not limited thereto, but can also be applied to a configuration example (second example) which p-type impurities are introduced into the semiconductor substrate SUB, the epitaxial layer EPI, and the semiconductor region 10.

In particular, corresponding to the manufacturing method of the first embodiment that utilizes the difference in thermal diffusion coefficients between phosphorus and arsenic, which are n-type impurities, the semiconductor region 10 can also be formed by utilizing the difference in thermal diffusion coefficients between indium and boron, which are p-type impurities. That is, the semiconductor region 10 can be formed by utilizing the fact that the thermal diffusion coefficient of boron is greater than that of indium. In this case, indium is introduced into the semiconductor substrate SUB. On the other hand, boron is introduced into each of the epitaxial layer EPI and the semiconductor region 10.

From the viewpoint of reducing the on-resistance, the first example in which n-type impurities are introduced is more desirable than the second example in which p-type impurities are introduced. This is because, in the first example, electrons serve as the majority carriers, whereas in the second example, holes are the majority carriers; and the mobility of electrons is higher than that of holes. That is, the first example, in which electrons with high mobility are the majority carriers, can achieve lower on-resistance than the second example, in which holes with lower mobility are the majority carriers.

What is claimed is:

1. A semiconductor device comprising:
a semiconductor substrate into which a first impurity of a first conductivity type is introduced;
a semiconductor layer formed on the semiconductor substrate and into which a second impurity of the first conductivity type is introduced;
an element formation layer formed on the semiconductor layer and having a first portion and a second portion; and
a semiconductor region formed in a portion of the semiconductor layer located under the first portion, into which a third impurity of the first conductivity type is introduced, the semiconductor region having an impurity concentration higher than an impurity concentration of the semiconductor layer.

2. The semiconductor device according to claim 1,
wherein the third impurity is an element different from the first impurity.

3. The semiconductor device according to claim 2,
a thermal diffusion coefficient of the third impurity is greater than a thermal diffusion coefficient of the first impurity.

4. The semiconductor device according to claim 1,
wherein the first conductivity type is an n-type.

5. The semiconductor device according to claim 4,
wherein the first impurity is arsenic, and
wherein the third impurity is phosphorus.

6. The semiconductor device according to claim 1,
wherein the second impurity and the third impurity are the same type of element.

7. The semiconductor device according to claim 1,
wherein a power transistor is formed in the first portion, and
wherein a MOSFET or an LDMOSFET is formed in the second portion.

8. The semiconductor device according to claim 1,
wherein an output circuit is formed in the first portion, and
wherein a control circuit that controls the output circuit is formed in the second portion.

9. The semiconductor device according to claim 1,
wherein the semiconductor region is in contact with the semiconductor substrate.

10. The semiconductor device according to claim 1,
wherein the semiconductor region is separated from the semiconductor substrate.

11. The semiconductor device according to claim 1,
wherein the semiconductor layer includes:
a first epitaxial layer formed on the semiconductor substrate, and
a second epitaxial layer formed on the first epitaxial layer, and
wherein the semiconductor region is formed in a portion of the first epitaxial layer located under the first portion.

12. The semiconductor device according to claim 1,
wherein the semiconductor region includes:
a first semiconductor region, and
a second semiconductor region formed over the first semiconductor region.

13. The semiconductor device according to claim 12,
wherein the first semiconductor region and the second semiconductor region are in contact with each other.

14. The semiconductor device according to claim 12,
wherein the first semiconductor region and the second semiconductor region are separated from each other.

15. A method of manufacturing a semiconductor device, the method comprising:
(a) preparing a semiconductor substrate into which a first impurity of a first conductivity type is introduced;
(b) introducing a third impurity of a first conductivity type having a thermal diffusion coefficient greater than a thermal diffusion coefficient of the first impurity into a first surface portion of the semiconductor substrate;
(c) after the (b), forming an epitaxial layer into which a second impurity of a first conductivity type is introduced is formed by epitaxial growth on the semiconductor substrate.

16. The method according to claim 15,
wherein the first conductivity type is an n-type,
wherein the first impurity is arsenic, and
wherein the third impurity is phosphorus.

17. A method of manufacturing a semiconductor device, the method comprising:
(a) preparing a semiconductor substrate into which a first impurity of a first conductivity type is introduced;
(b) forming a first epitaxial layer on the semiconductor substrate by epitaxial growth, the first epitaxial layer having a first impurity concentration into which a second impurity of the first conductivity type is introduced;
(c) introducing a third impurity of the first conductivity type into a first portion of the first epitaxial layer, thereby making an impurity concentration in the first portion greater than the first impurity concentration; and
(d) after the (c), forming a second epitaxial layer into which a fourth impurity of the first conductivity type is introduced on the first epitaxial layer by epitaxial growth.

18. The method according to claim 17,
wherein the first conductivity type is an n-type,
wherein the first impurity is arsenic,
wherein the second impurity is phosphorus,
wherein the third impurity is phosphorus, and
wherein the fourth impurity is phosphorus.
